(19) United States
(12) Patent Application Publication
(10) Pub. No.: US 2026/0123198 A1
(43) Pub. Date: Apr. 30, 2026

(54) DISPLAY PANEL AND ELECTRONIC APPRATUS INCLUDING THE SAME

(71) Applicant: Samsung Display Co., LTD., Yongin-si (KR)

(72) Inventors: Hyungil Jeon, Yongin-si (KR); Gyujeong Lee, Yongin-si (KR); Changil Tae, Yongin-si (KR)

(21) Appl. No.: 19/289,557

(22) Filed: Aug. 4, 2025

(30) Foreign Application Priority Data
Oct. 31, 2024 (KR) 10-2024-0152956

(51) Int. Cl. H10K 59/124; H10H 29/41

(52) U.S. Cl. CPC H10K 59/124; H10H 29/41

(57) ABSTRACT

A display panel includes a substrate, a pixel circuit layer including a pixel circuit and insulating layers and disposed on the substrate, and a light-emitting diode disposed on the pixel circuit layer and electrically connected to the pixel circuit. The pixel circuit of the pixel circuit layer includes a driving transistor and a storage capacitor. The driving transistor includes a semiconductor layer and a gate electrode, the insulating layers of the pixel circuit layer include a first insulating layer disposed between the semiconductor layer and the gate electrode, and the first insulating layer includes a first inorganic material portion that overlaps the gate electrode and a first organic material portion around the first inorganic material portion.

This application claims priority to Korean Patent Application No. 10-2024-0152956, filed on October 31, 2024, and all the benefits accruing therefrom under 35 U.S.C. §119, the content of which in its entirety is herein incorporated by reference.

### BACKGROUND

### 1. Field

Embodiments relate to a display panel. Embodiments relate to a display panel, a manufacturing process for the display panel, and an electronic apparatus including the display panel.

### 2. Description of the Related Art

In general, with the developments in display panels that visually display electrical signals, various display panels with excellent features, such as relatively small thickness, relatively light weight, and relatively low power consumption, and electronic apparatuses including such display panels are being introduced. For example, research is being actively conducted on display panels having various structures, for example, flexible display panels that are foldable or rollable, and stretchable display panels, and electronic apparatuses including such display panels.

### SUMMARY

Embodiments include configurations of a display panel and an electronic apparatus including the same.

Additional features will be set forth in part in the description which follows and, in part, will be apparent from the description, or may be learned by practice of the presented embodiments of the disclosure.

In an embodiment of the disclosure, a display panel includes a substrate, a pixel circuit layer on the substrate and including a pixel circuit and a plurality of insulating layers, and a light-emitting diode on the pixel circuit layer and electrically connected to the pixel circuit. The pixel circuit of the pixel circuit layer includes a driving transistor and a storage capacitor. The driving transistor includes a semiconductor layer and a gate electrode, the plurality of insulating layers of the pixel circuit layer includes a first insulating layer disposed between the semiconductor layer and the gate electrode, and the first insulating layer includes a first inorganic material portion overlapping the gate electrode and a first organic material portion around the first inorganic material portion.

In an embodiment, an upper surface of the first inorganic material portion and an upper surface of the first organic material portion may be arranged in a same plane.

In an embodiment, in a plan view, the first organic material portion may surround an entirety of the first inorganic material portion.

In an embodiment, the first organic material portion may include a 1-1^{st} organic material portion that overlaps the semiconductor layer, and a 1-2^{nd} organic material portion that does not overlap the semiconductor layer, and a thickness of the first inorganic material portion may be less than a thickness of the 1-2^{nd} organic material portion.

In an embodiment, a thickness of the 1-1^{st} organic material portion may be substantially a same as the thickness of the first inorganic material portion.

In an embodiment, the plurality of insulating layers may further include a second insulating layer disposed between a first electrode and a second electrode of the storage capacitor, and the second insulating layer may include a second inorganic material portion overlapping the first electrode and the second electrode and a second organic material portion around the second inorganic material portion.

In an embodiment, an upper surface of the second inorganic material portion and an upper surface of the second organic material portion may be arranged in a same plane.

In an embodiment, the second inorganic material portion may overlap the first inorganic material portion.

In an embodiment, the pixel circuit layer may include a switching transistor electrically connected to the driving transistor and a connector connecting to a semiconductor layer of the switching transistor, and the connector may directly contact the semiconductor layer of the switching transistor through a contact hole that penetrates insulating layers arranged between the semiconductor layer of the switching transistor and the connector among the plurality of insulating layers, the contact hole passing through each of organic material portions of the insulating layers arranged between the semiconductor layer and the connector.

In an embodiment of the disclosure, a display panel includes a substrate, a pixel circuit layer on the substrate and including a pixel circuit and a plurality of insulating layers, and a light-emitting diode on the pixel circuit layer and electrically connected to the pixel circuit. The pixel circuit of the pixel circuit layer includes a driving transistor and a storage capacitor, the driving transistor including a semiconductor layer and a gate electrode, the plurality of insulating layers of the pixel circuit layer include a first insulating layer between the substrate and the semiconductor layer, a second insulating layer between the semiconductor layer and the gate electrode, and a third insulating layer on the second insulating layer, and at least one of the first insulating layer to the third insulating layer includes a plurality of inorganic material portions spaced apart from each other and an organic material portion that surrounds each of the plurality of inorganic material portions in a plan view.

In an embodiment, an upper surface of each of the plurality of inorganic material portions and an upper surface of the organic material portion may be arranged in a same plane.

In an embodiment, the first insulating layer may include a first inorganic material portion that overlaps the semiconductor layer and a first organic material portion around the first inorganic material portion.

In an embodiment, the second insulating layer may include a second inorganic material portion that overlaps the gate electrode and a second organic material portion around the second inorganic material portion.

In an embodiment, the second organic material portion may include a 2-1^{st} organic material portion that overlaps the semiconductor layer and a 2-2^{nd} organic material portion that does not overlap the semiconductor layer, and a thickness of the 2-2^{nd} organic material portion may be greater than a thickness of the 2-1^{st} organic material portion.

In an embodiment, a thickness of the second inorganic material portion may be less than the thickness of the 2-2^{nd} organic material portion.

In an embodiment, the thickness of the second inorganic material portion may be substantially a same as the thickness of the 2-1^{st} organic material portion.

In an embodiment, the storage capacitor may include a first electrode and a second electrode, the first electrode of the storage capacitor is integrally coupled to the gate electrode, and the third insulating layer may include a third inorganic material portion overlapping the first electrode and the second electrode of the storage capacitor and a third organic material portion around the third inorganic material portion.

In an embodiment, an upper surface of the second inorganic material portion and an upper surface of the second organic material portion may be arranged in a same plane.

In an embodiment, the third inorganic material portion may overlap the second inorganic material portion.

In an embodiment, the pixel circuit layer may include a switching transistor electrically connected to the driving transistor, and a connector connecting to a semiconductor layer of the switching transistor, and the connector may directly contact the semiconductor layer of the switching transistor through a contact hole that penetrates insulating layers arranged between the semiconductor layer of the switching transistor and the connector among the plurality of insulating layers, the contact hole passing through each of organic material portions of the insulating layers arranged between the semiconductor layer and the connector.

In an embodiment of the disclosure, an electronic apparatus includes the display section according to the embodiments. The electronic apparatus may include a frame, a display panel assembled to the frame and corresponding to the display section, and a stroke assembled to the frame and disposed under the display panel.

In an embodiment, the electronic apparatus may include a wearable electronic apparatus.

In an embodiment, the display panel may be three-dimensionally stretchable by the stroke.

In an embodiment, the display section may have a dome shape when the display panel is not three-dimensionally stretched.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic perspective view of an embodiment of a display panel;

FIGS. 2A and 2B are perspective views showing states in which the display panel of FIG. 1 extends in a first direction;

FIG. 2C is a perspective view showing a state in which the display panel of FIG. 1 extends in a second direction;

FIG. 2D is a perspective view showing a state in which the display panel of FIG. 1 extends in the first direction and the second direction;

FIG. 2E is a perspective view showing a state in which the display panel of FIG. 1 extends in a third direction;

FIGS. 3A to 3C are respectively schematic plan views showing an embodiment of excerpts of a display area of a display panel;

FIGS. 4A to 4C are respectively equivalent circuit diagrams of an embodiment of pixels of a display panel;

FIGS. 5A to 5E are respectively schematic cross-sectional views of an embodiment of light-emitting diodes of a display panel;

FIG. 6 is a schematic cross-sectional view of an embodiment of a portion of a first area of a display panel;

FIGS. 7A to 7C are schematic plan views of an embodiment of an insulating layer included in a display panel;

FIG. 8 is a cross-sectional view of an embodiment of a portion of a pixel circuit layer of a display panel;

FIG. 9 is a plan view of an embodiment of a first insulating layer of a display panel;

FIG. 10 is a plan view of an embodiment of a semiconductor layer of a display panel;

FIG. 11 is a plan view of an embodiment of a second insulating layer of a display panel;

FIG. 12 is a plan view of an embodiment of a first conductive layer of a display panel;

FIG. 13 is a plan view of an embodiment of a third insulating layer of a display panel;

FIG. 14 is a plan view of an embodiment of a second conductive layer of a display panel;

FIG. 15 is a plan view of an embodiment of a fourth insulating layer of a display panel;

FIG. 16 is a plan view of an embodiment of a third conductive layer of a display panel;

FIG. 17 is a schematic perspective view of an embodiment of an electronic apparatus including a display panel;

FIG. 18 is a block diagram of an embodiment of an electronic apparatus including a display panel;

FIGS. 19A and 19B are respectively perspective views of an embodiment of electronic apparatuses;

FIG. 20 is a perspective view of an embodiment of an electronic apparatus; and

FIG. 21 is a perspective view of an embodiment of an electronic apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b, and c" or "at least one selected from a, b, and c" indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, embodiments of the disclosure will be described in detail with reference to the accompanying drawings. Like elements in the drawings denote like elements, and repeated descriptions thereof are omitted.

It will be understood that although the terms "first," "second," etc. may be used herein to describe various elements, these elements should not be limited by these terms, and these elements are only used to distinguish one element from another.

As used herein, the singular forms "a," "an," and "the" are intended to include the plural forms as well, unless the context clearly indicates otherwise.

It will be further understood that the terms "comprises" and/or "comprising" used herein specify the presence of stated features or elements, but do not preclude the presence or addition of one or more other features or elements.

It will be understood that when a layer, region, or element is referred to as being "formed on" another layer, region, or element, it may be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following disclosure is not limited thereto.

When an illustrative embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it may be directly or indirectly connected to the other layer, region, or component. For example, when a layer, region, or component is referred to as being electrically connected to another layer, region, or component, it may be directly or indirectly electrically connected to the other layer, region, or component.

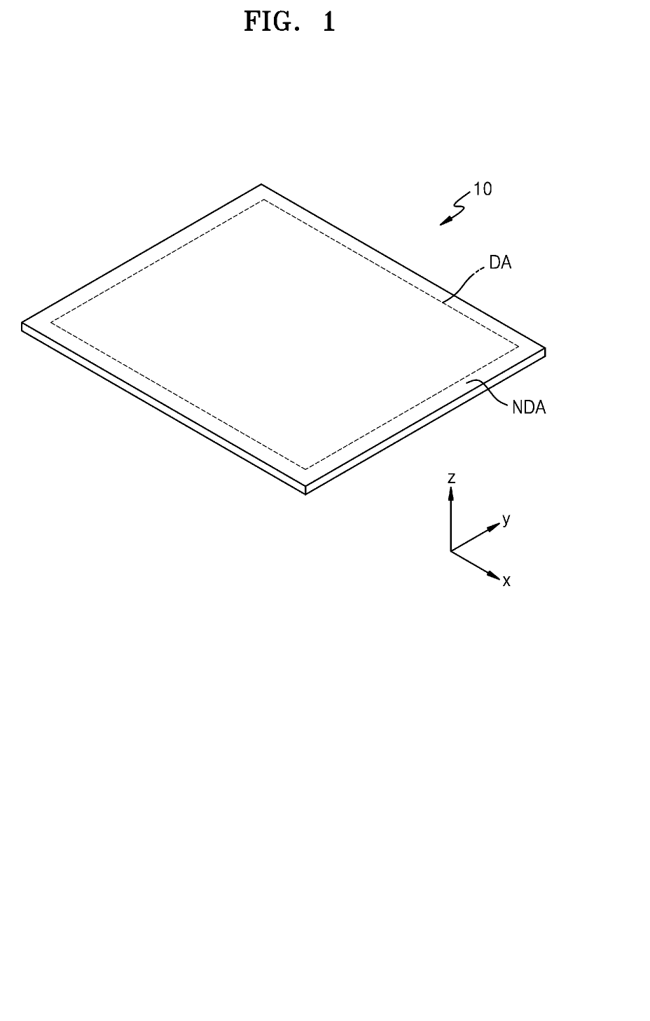

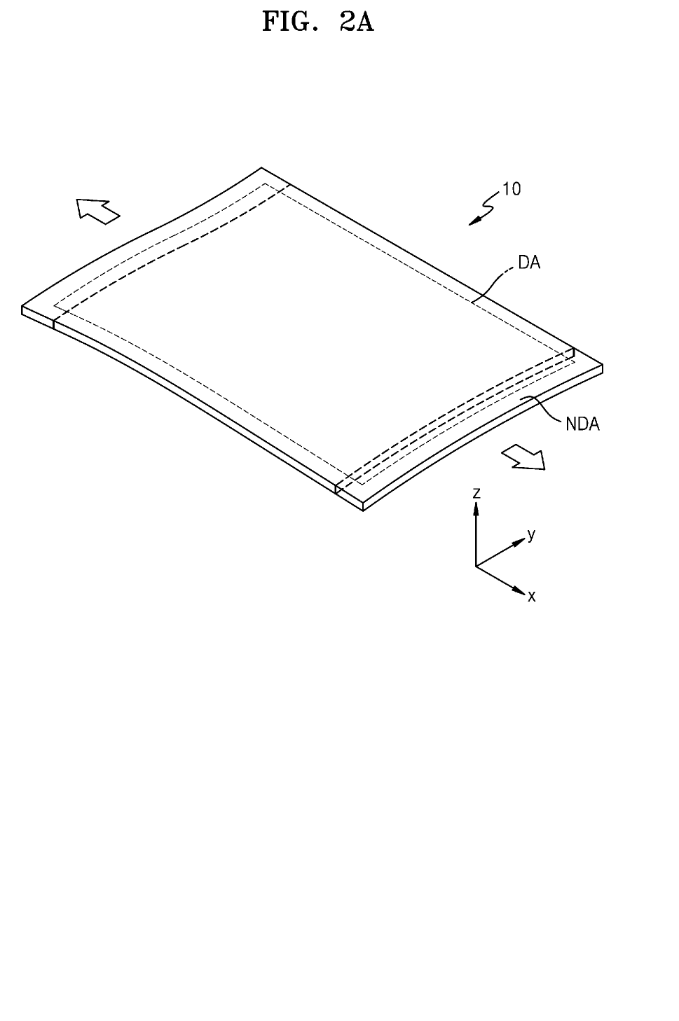

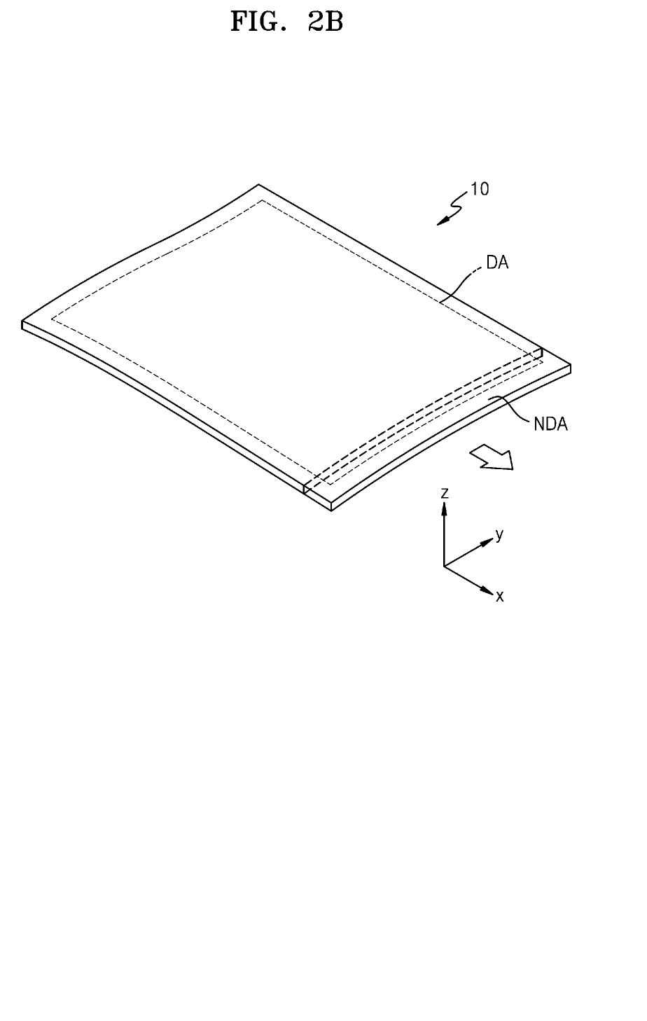

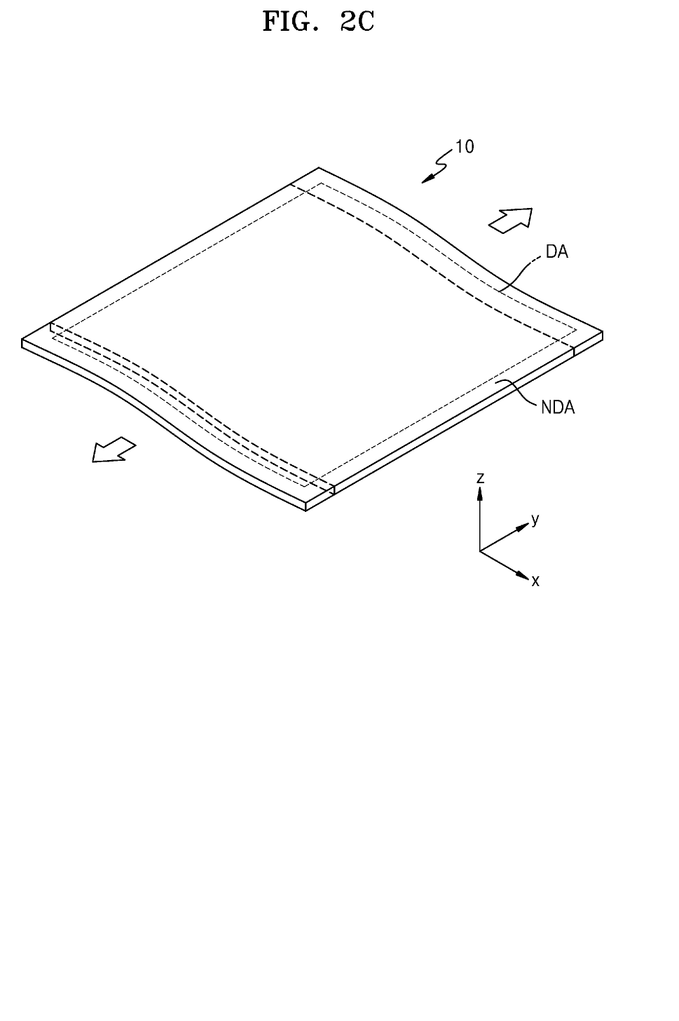

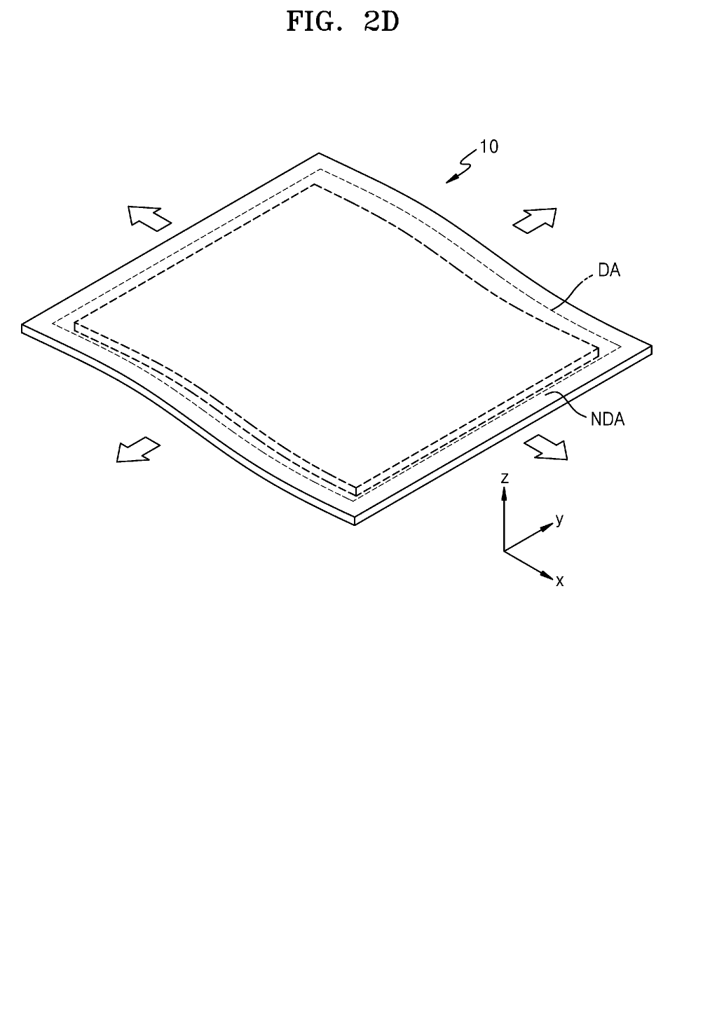

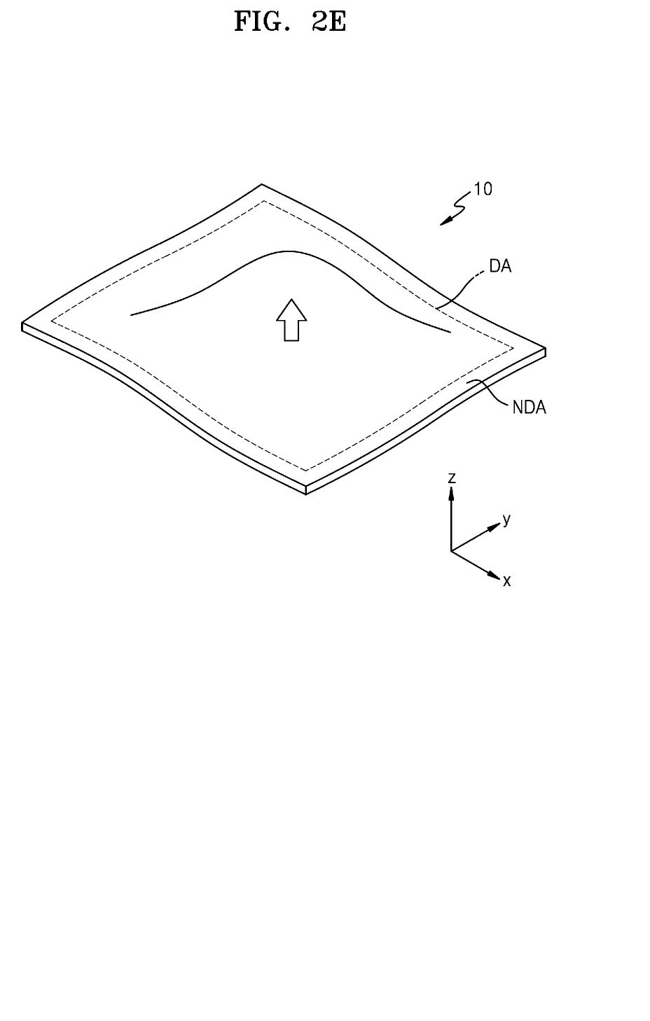

FIG. 1 is a schematic perspective view of an embodiment of a display panel 10. FIGS. 2A and 2B are perspective views showing states in which the display panel 10 of FIG. 1 extends in a first direction. FIG. 2C is a perspective view showing a state in which the display panel 10 of FIG. 1 extends in a second direction. FIG. 2D is a perspective view showing a state in which the display panel 10 of FIG. 1 extends in the first direction and the second direction. FIG. 2E is a perspective view showing a state in which the display panel 10 of FIG. 1 extends in a third direction.

Referring to FIG. 1, the display panel 10 may include a display area DA and a non-display area NDA. The display area DA may include a plurality of pixels. The display panel 10 may provide predetermined images by light emitted from the plurality of pixels. The non-display area NDA may be outside the display area DA. The non-display area NDA may surround an entirety of the display area DA.

The display panel 10 may extend or contract in various directions. The display panel 10 may be stretched in the first direction (e.g., the x direction and/or the -x direction) by an external force applied by an external object or a user. In an embodiment, as shown in FIGS. 2A and 2B, the display area DA and/or the non-display area NDA of the display panel 10 may be stretched in the first direction (e.g., the x direction and/or the -x direction). In an embodiment, as shown in FIG. 2A, the display area DA and/or the non-display area NDA of the display panel 10 may be stretched in the x direction or -x direction, or as shown in FIG. 2B, the display area DA and/or the non-display area NDA may be stretched in the x direction with one side of the display panel 10 fixed, for example.

The display panel 10 may be stretched in the second direction (e.g., the y direction and/or the -y direction) by an external force applied by an external object or a user. In an embodiment, as shown in FIG. 2C, the display area DA and/or the non-display area NDA of the display panel 10 may be stretched in the y direction and the -y direction. In another embodiment, the display area DA and/or the non-display area NDA of the display panel 10 may be stretched in the y direction or the -y direction with one side of the display panel 10 fixed.

The display panel 10 may be stretched in multiple directions, such as the first direction (e.g., the x direction and/or the -x direction) and the second direction (e.g., the y direction and/or the -y direction), by an external force applied by an external object or a body part of a person. As shown in FIG. 2D, the display area DA and/or the non-display area NDA of the display panel 10 may be stretched in the ±x direction and the ±y direction.

The display panel 10 may be stretched in the third direction (e.g., the z direction or the -z direction) by an external force applied by an external object or a body part of a person. In an embodiment, FIG. 2E illustrates that a portion of the display panel 10, e.g., a portion of the display area DA, protrudes in the z direction. In another embodiment, a portion of the display panel 10, e.g., a portion of the display area DA, may protrude in the z direction (or may be recessed in the -z direction).

FIGS. 2A to 2E illustrate that the display panel 10 is stretched in the first direction, the second direction, and/or the third direction, but the disclosure is not limited thereto. In another embodiment, the display panel 10 may be variously deformed into atypical forms; for example, the display panel 10 may be bent or twisted around two or more axes.

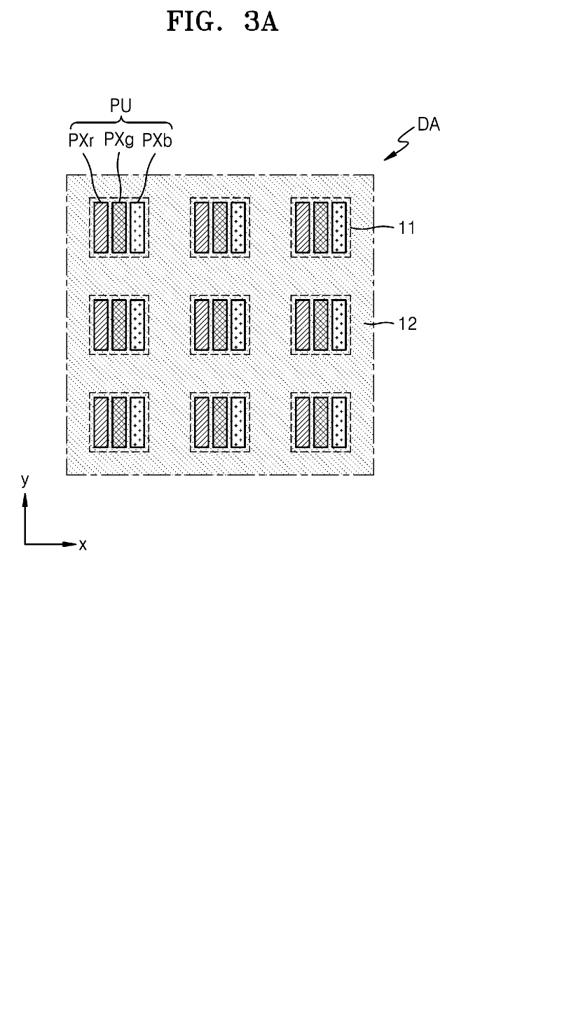

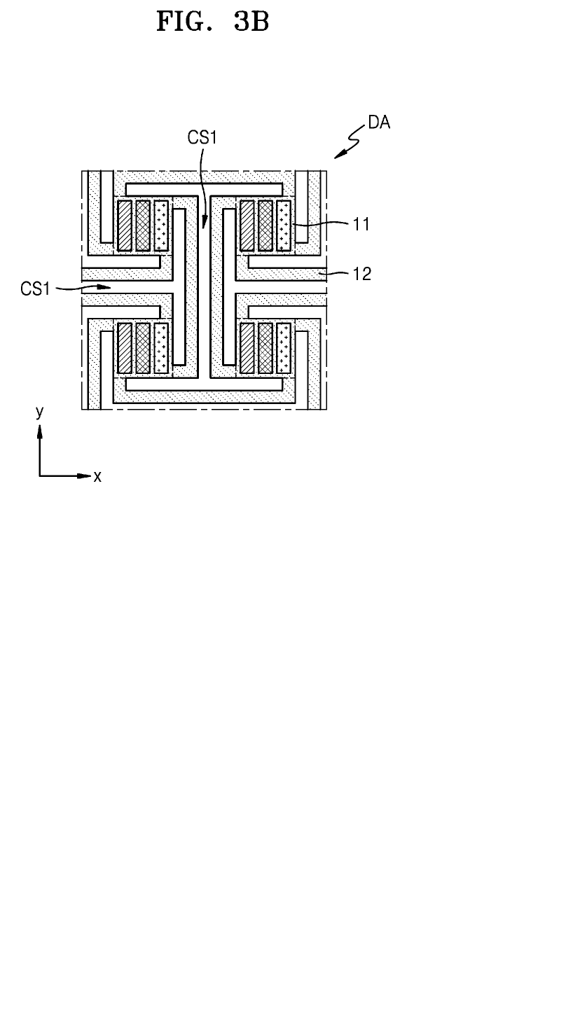

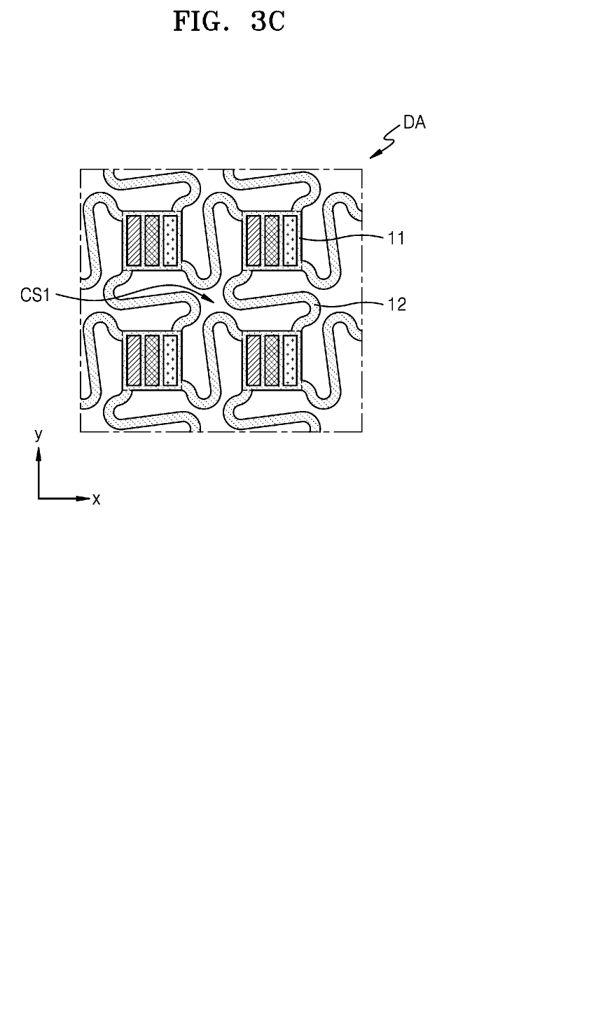

FIGS. 3A to 3C are respectively schematic plan views showing an embodiment of excerpts of the display area DA of a display panel.

Referring to FIGS. 3A to 3C, the display area DA may include first areas 11 and a second area 12 connecting the first areas 11.

The display area DA may include the first area 11 and the second area 12 with different elongations. In an embodiment, the display panel 10 may include the first area 11 having relatively low elongation and the second area 12 having relatively high elongation, for example. In the specification, elongation refers to the value indicating a change (L/L) in length by which the display panel 10 may be stretched without physical damage thereto when an external force is applied to the display panel 10. Here, L represents a variation in length of the display panel 10, and L represents the initial length of the display panel 10. Therefore, the elongation of each of the first area 11 and the second area 12 may indicate the change in length of each of the first area 11 and the second area 12 when the same external force is applied thereto.

The description that the elongation of the first area 11 is less than that of the second area 12 may indicate that the first area 11 undergoes less deformation caused by an external force. Therefore, the first area 11 may be also referred to as a relatively low deformation area, and the second area 12 may be also referred to as a relatively high deformation area.

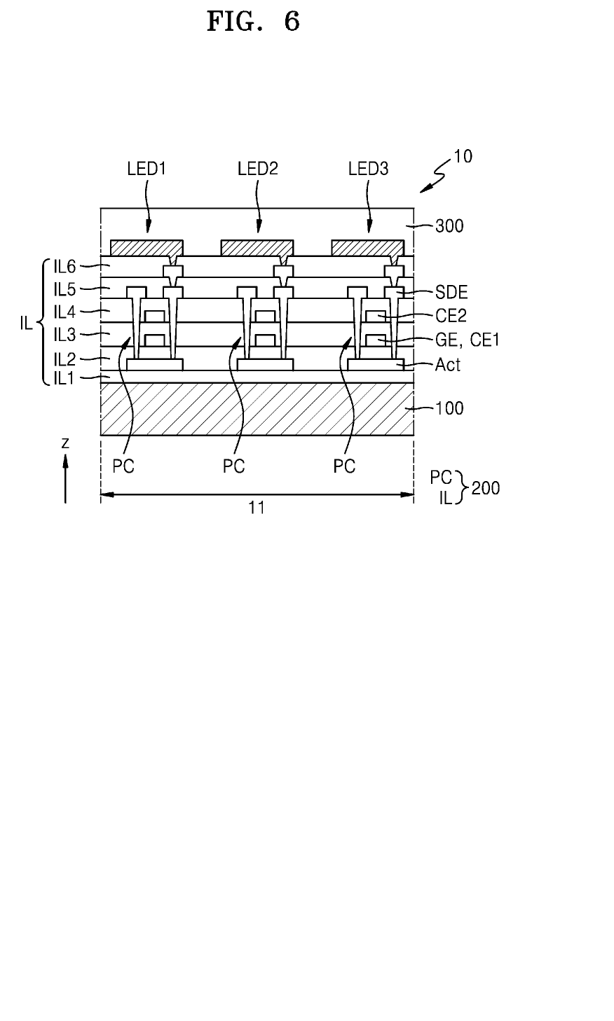

The first areas 11 may be spaced apart from each other and two-dimensionally arranged in the display area DA. The first areas 11 may be repeatedly arranged in the first direction (e.g., the x direction) and the second direction (e.g., the y direction). The first area 11 may be an area where pixels PXr, PXg and PXb of a pixel unit PU are arranged and thus may be also referred to as the pixel area or the emission area. In each first area 11, one or more pixels may be arranged. In the first area 11, light-emitting diodes LED1 to LED3 (refer to FIG. 6) corresponding to the pixels PXr, PXg and PXb may be arranged. FIGS. 3A to 3C illustrate that three light-emitting diodes LED1 to LED3 are arranged in the first area 11, but the number of light-emitting diodes LED1 to LED3 arranged in the first area 11 may vary. The light-emitting diodes LED1 to LED3 may emit different colors of light, e.g., red, green, and blue.

In the first area 11, a pixel circuit for operations of the light-emitting diodes LED1 to LED3 may be arranged. The pixel circuit may include a transistor and a capacitor.

The second area 12 may be disposed between first areas 11 next (adjacent) to each other. In an embodiment, as shown in FIG. 3A, the second area 12 may have a shape surrounding each of the first areas 11 in a plan view. In an embodiment, as shown in FIG. 3A, the second area 12 may surround each of the first areas 11. In an embodiment, as shown in FIG. 3B or 3C, the second area 12 may be patterned. In an embodiment, as shown in FIGS. 3B and 3C, the second area 12 may define cutout areas CS1, for example. As shown in FIG. 3B, the second area 12 may include an arrangement of the cutout areas CS1 having the shape of the letter H, and between two cutout areas CS1 next (adjacent) to each other, another cutout area CS1 that is rotated by 90 degrees may be disposed. As shown in FIG. 3C, the second area 12 may include an arrangement of cutout areas CS1 in the shape of four-bladed propellers.

The second area 12 may be a region where lines (e.g., gate lines, data lines, first voltage lines, second voltage lines, etc.) pass, where the lines are respectively and electrically connected to pixel circuits respectively arranged in two first areas 11 next (adjacent) to each other.

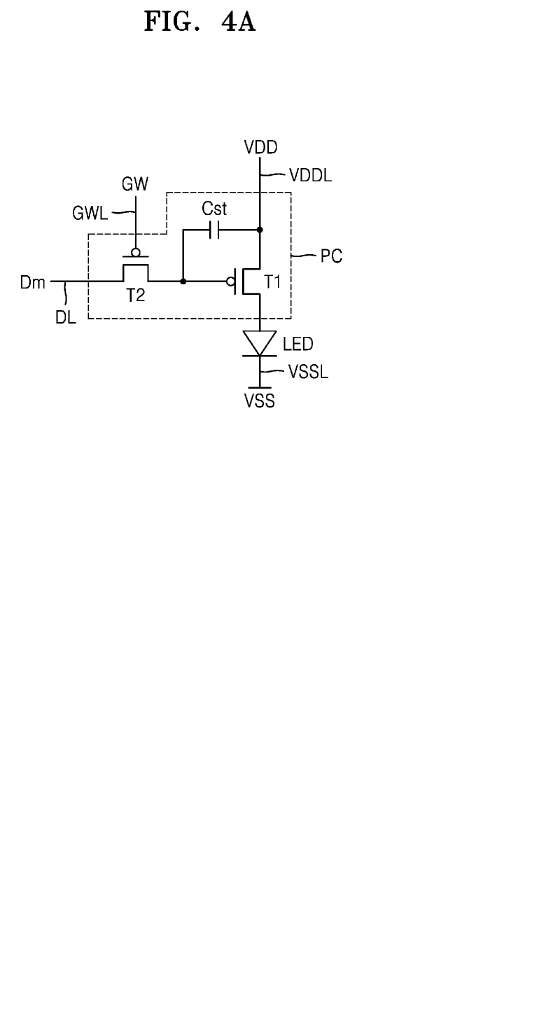

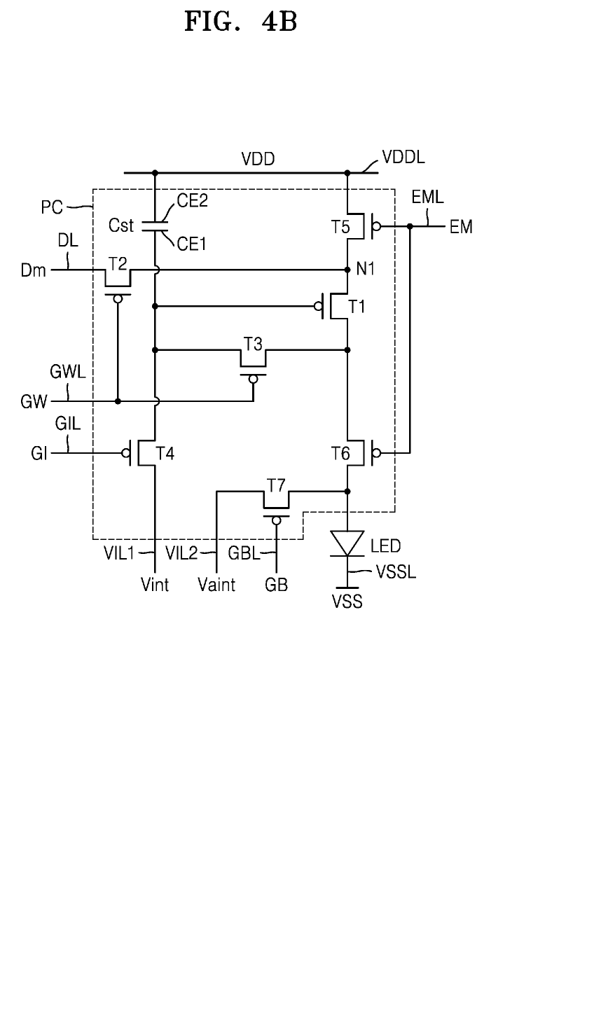

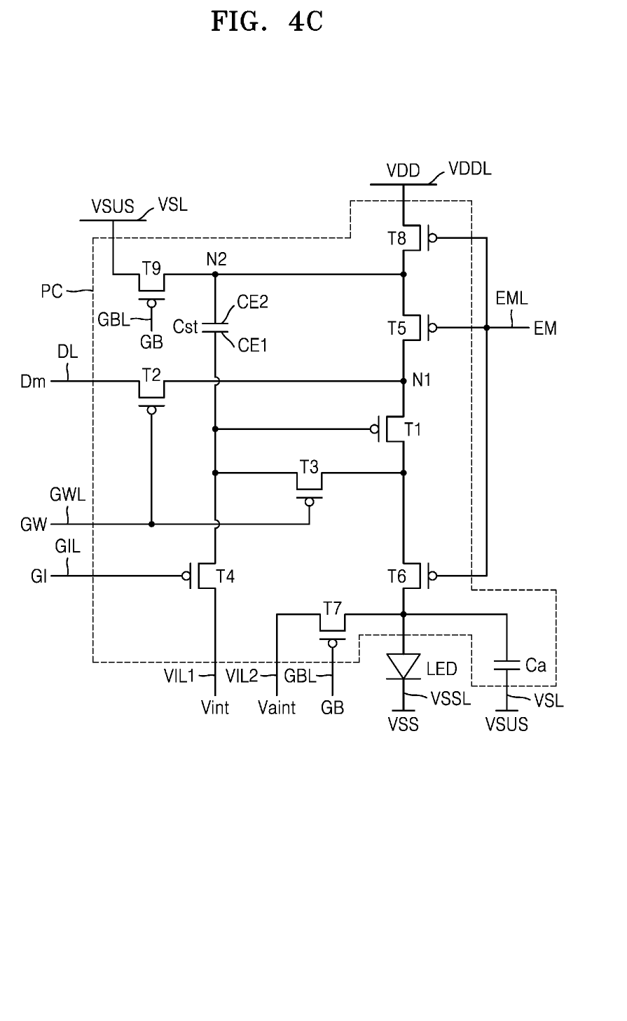

FIGS. 4A to 4C are respectively equivalent circuit diagrams of an embodiment of pixels of a display panel.

Referring to FIG. 4A, a light-emitting diode LED corresponding to a pixel may be electrically connected to a pixel circuit PC, and the pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL.

The second transistor T2 may be a data write transistor and may be electrically connected to the scan signal line GWL and the data line DL. The scan signal line GWL may provide a scan signal GW to a gate electrode of the second transistor T2. The second transistor T2 may transmit, to the first transistor T1, a data signal Dm that is input through the data line DL, according to the scan signal GW that is input through the scan signal line GWL.

The storage capacitor Cst may be electrically connected to the second transistor T2 and the first voltage line VDDL and may store a voltage corresponding to a difference between a voltage from the second transistor T2 and a first power voltage VDD provided through the first voltage line VDDL.

The first transistor T1 may be a driving transistor and may control a driving current flowing through the light-emitting diode LED. The first transistor T1 may be connected between the first voltage line VDDL and the storage capacitor Cst. The first transistor T1 may control a driving current flowing from the first voltage line VDDL to the light-emitting diode LED, according to the voltage stored in the storage capacitor Cst. The light-emitting diode LED may emit light having a predetermined brightness because of the driving current. A first electrode of the light-emitting diode LED may be electrically connected to the first transistor T1, and a second electrode of the light-emitting diode LED may be electrically connected to a second voltage line VSSL which provides a second power voltage VSS.

FIG. 4A illustrates that the pixel circuit PC includes one switching transistor (e.g., the second transistor T2) and one capacitor (e.g., the storage capacitor Cst), but in another embodiment, the pixel circuit PC may include at least two switching transistors and/or at least two capacitors.

Referring to FIG. 4B, a pixel circuit PC may include a first transistor T1, a second transistor T2, a third transistor T3, a fourth transistor T4, a fifth transistor T5, a sixth transistor T6, a seventh transistor T7, and a storage capacitor Cst. The first transistor T1 is a driving transistor, and each of the second transistor T2, the third transistor T3, the fourth transistor T4, the fifth transistor T5, the sixth transistor T6, and the seventh transistor T7 is a switching transistor.

The pixel circuit PC is electrically connected to signal lines and voltage lines. The signal lines may include gate lines, such as a scan signal line GWL, a bypass control line GBL, an initialization control line GIL, and an emission control line EML, and a data line DL. The voltage lines may include a first initialization voltage line VIL1, a second initialization voltage line VIL2, and a first voltage line VDDL.

The first voltage line VDDL may transmit the first power voltage VDD to the first transistor T1. The first initialization voltage line VIL1 may transmit, to the pixel circuit PC, a first initialization voltage Vint which initializes the first transistor T1. The second initialization voltage line VIL2 may transmit, to the pixel circuit PC, a second initialization voltage Vaint which initializes the first electrode of the light-emitting diode LED.

The first transistor T1 may be electrically connected to the first voltage line VDDL via the fifth transistor T5 and to the light-emitting diode LED via the sixth transistor T6. The first transistor T1 functions as a driving transistor and receives a data signal Dm according to a switching operation of the second transistor T2, thereby providing a driving current to the light-emitting diode LED.

The second transistor T2 is a data write transistor and electrically connected to the scan signal line GWL and the data line DL. The second transistor T2 is electrically connected to the first voltage line VDDL via the fifth transistor T5. The second transistor T2 is turned on in response to the scan signal GW transmitted through the scan signal line GWL and performs a switching operation in which the data signal Dm transmitted through the data line DL is transmitted to a first node N1.

The third transistor T3 is electrically connected to the scan signal line GWL and to the light-emitting diode LED via the sixth transistor T6. The third transistor T3 may be turned on in response to the scan signal GW transmitted through the scan signal line GWL and may diode-connect the first transistor T1.

The fourth transistor T4 is a first initialization transistor and electrically connected to an initialization control line GIL and the first initialization voltage line VIL1. The fourth transistor T4 is turned on in response to an initialization control signal GI transmitted through the initialization control line GIL and transmits the first initialization voltage Vint from the first initialization voltage line VIL1 to a gate electrode of the first transistor T1, thereby initializing a voltage of the gate electrode of the first transistor T1. The initialization control signal GI may correspond to a scan signal of another pixel circuit in a previous row of the corresponding pixel circuit PC.

The fifth transistor T5 may be an operation control transistor, and the sixth transistor T6 may be an emission control transistor. The fifth transistor T5 and the sixth transistor T6 are electrically connected to the emission control line EML and simultaneously turned on according to an emission control signal EM transmitted through the emission control line EML, thus forming a current path to allow the driving current to flow from the first voltage line VDDL to the light-emitting diode LED. The first electrode of the light-emitting diode LED may be electrically connected to the first transistor T1 through the sixth transistor T6, and the second electrode of the light-emitting diode LED may be electrically connected to the second voltage line VSSL which provides the second power voltage VSS.

The seventh transistor T7 may be a second initialization transistor and electrically connected to the bypass control line GBL, the second initialization voltage line VIL2, and the sixth transistor T6. The seventh transistor T7 may be turned on in response to a bypass control signal GB transmitted through the bypass control line GBL and may transmit the second initialization voltage Vaint from the second initialization voltage line VIL2 to the first electrode of the light-emitting diode LED, thereby initializing the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may store and maintain a voltage corresponding to a difference in voltages of the first voltage line VDDL and opposite ends of the gate electrode of the first transistor T1 so that a voltage applied to the gate electrode of the first transistor T1 may be maintained.

Referring to FIG. 4C, a pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca. The first transistor T1 is a driving transistor, and each of the second transistor T2, the third transistor T3, the fourth transistor T4, the fifth transistor T5, the sixth transistor T6, the seventh transistor T7, the eighth transistor T8, and the ninth transistor T9 is a switching transistor.

The pixel circuit PC is electrically connected to signal lines and voltage lines. The signal lines may include gate lines, such as a scan signal line GWL, a bypass control line GBL, an initialization control line GIL, and an emission control line EML, and a data line DL. The voltage lines may include a first initialization voltage line VIL1, a second initialization voltage line VIL2, a sustaining voltage line VSL, and a first voltage line VDDL.

The first voltage line VDDL may transmit the first power voltage VDD to the first transistor T1. The first initialization voltage line VIL1 may transmit, to the pixel circuit PC, a first initialization voltage Vint which initializes the first transistor T1. The second initialization voltage line VIL2 may transmit, to the pixel circuit PC, a second initialization voltage Vaint which initializes the first electrode of the light-emitting diode LED. The sustaining voltage line VSL may provide a sustaining voltage VSUS to a second node N2, such as the second electrode CE2 of the storage capacitor Cst, in an initialization section and a data writing section.

The first transistor T1 may be electrically connected to the first voltage line VDDL via the fifth transistor T5 and the eighth transistor T8 and to the light-emitting diode LED via the sixth transistor T6. The first transistor T1 may function as a driving transistor and receive a data signal Dm according to a switching operation of the second transistor T2, thereby providing a driving current to the light-emitting diode LED.

The second transistor T2 is electrically connected to the scan signal line GWL and the data line DL and to the first voltage line VDDL via the fifth transistor T5 and the eighth transistor T8. The second transistor T2 is turned on in response to the scan signal GW transmitted through the scan signal line GWL and performs a switching operation in which the data signal Dm transmitted through the data line DL is transmitted to a first node N1.

The third transistor T3 is electrically connected to the scan signal line GWL and to the light-emitting diode LED via the sixth transistor T6. The third transistor T3 may be turned on in response to the scan signal GW transmitted through the scan signal line GWL and diode-connect the first transistor T1, thereby compensating for a threshold voltage of the first transistor T1.

The fourth transistor T4 is electrically connected to the initialization control line GIL and the first initialization voltage line VIL1, turned on in response to the initialization control signal GI transmitted through the initialization control line GIL, and transmits the first initialization voltage Vint from the first initialization voltage line VIL1 to the gate electrode of the first transistor T1, thereby initializing the voltage of the gate electrode of the first transistor T1. The initialization control signal GI may correspond to a scan signal of another pixel circuit in a previous row of the corresponding pixel circuit PC.

The fifth transistor T5, the sixth transistor T6, and the eighth transistor T8 are electrically connected to the emission control line EML and simultaneously turned on according to the emission control signal EM transmitted through the emission control line EML, thus forming a current path to allow the driving current to flow from the first voltage line VDDL to the light-emitting diode LED. The first electrode of the light-emitting diode LED may be electrically connected to the first transistor T1 through the sixth transistor T6, and the second electrode of the light-emitting diode LED may be electrically connected to the second voltage line VSSL which provides the second power voltage VSS.

The seventh transistor T7 may be a second initialization transistor and electrically connected to the bypass control line GBL, the second initialization voltage line VIL2, and the sixth transistor T6. The seventh transistor T7 is turned on in response to the bypass control signal GB transmitted through the bypass control line GBL and may transmit the second initialization voltage Vaint from the second initialization voltage line VIL2 to the first electrode of the light-emitting diode LED, thereby initializing the first electrode of the light-emitting diode LED.

The ninth transistor T9 may be electrically connected to the bypass control line GBL, the second electrode CE2 of the storage capacitor Cst, and the sustaining voltage line VSL. The ninth transistor T9 may be turned on in response to the bypass control signal GB transmitted through the bypass control line GBL and may transmit the sustaining voltage VSUS to the second node N2, such as the second electrode CE2 of the storage capacitor Cst, in the initialization section and the data writing section.

The eighth transistor T8 and the ninth transistor T9 may each be electrically connected to the second node N2, such as the second electrode CE2 of the storage capacitor Cst. In some embodiments, the eighth transistor T8 may be turned off and the ninth transistor T9 may be turned on in the initialization section and the data writing section, whereas the eighth transistor T8 may be turned on and the ninth transistor T9 may be turned off in the emission section.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustaining voltage line VSL, and the first electrode of the light-emitting diode LED. The auxiliary capacitor Ca may store and maintain the voltage corresponding to the voltage difference between the first electrode of the light-emitting diode LED and the sustaining voltage line VSL while the seventh transistor T7 and the ninth transistor T9 are turned on, thereby preventing the increase in black luminance when the sixth transistor T6 is off.

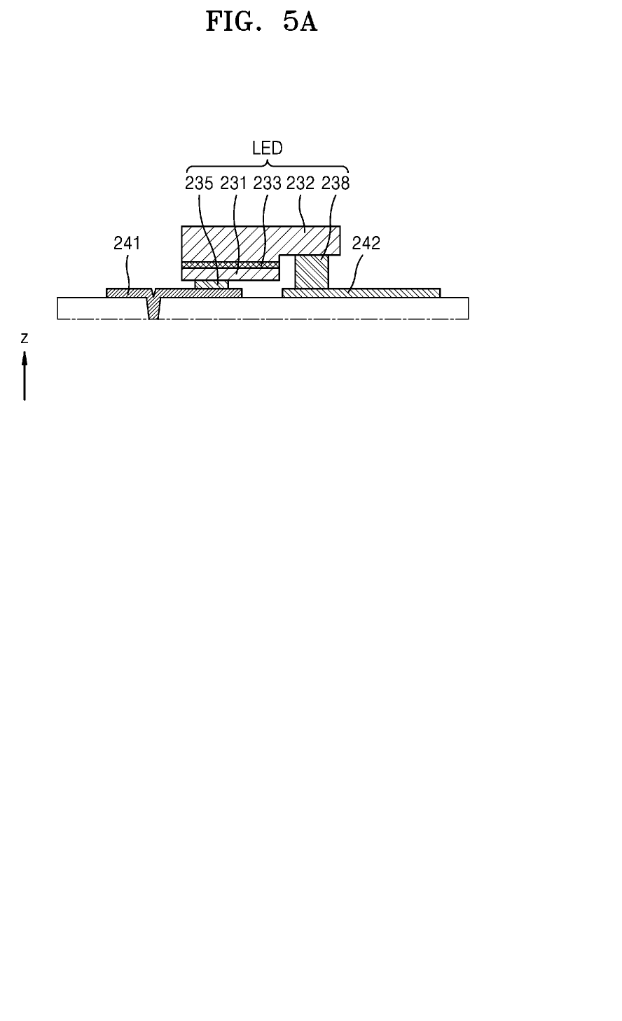

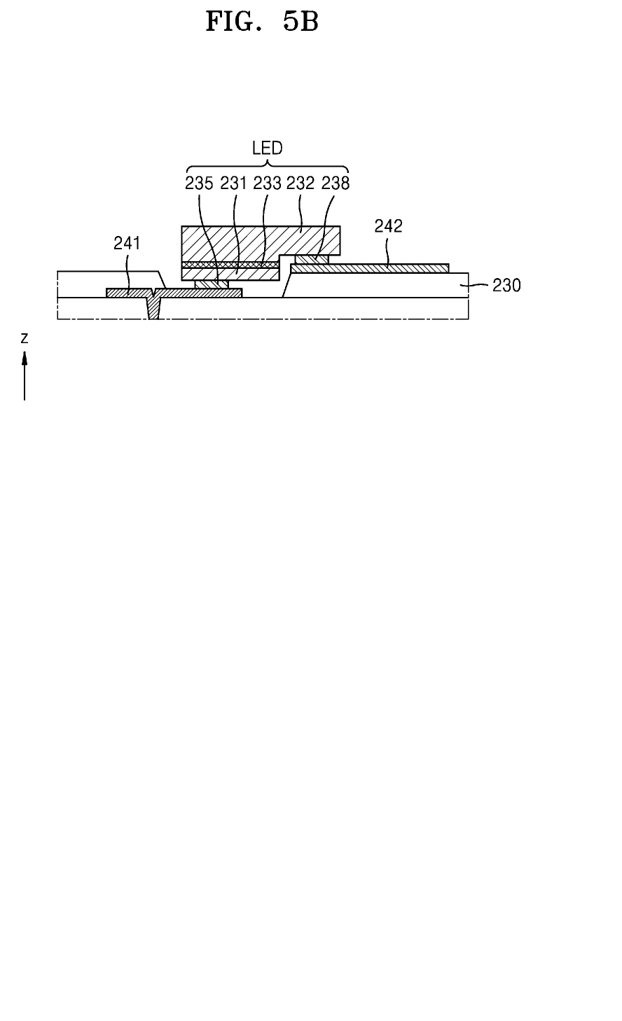

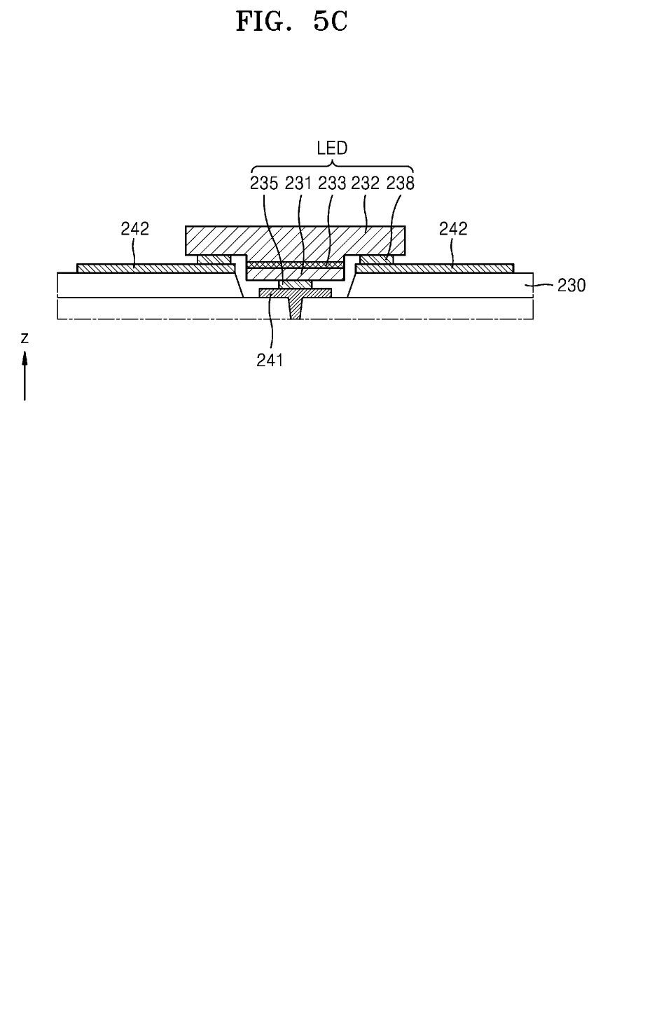

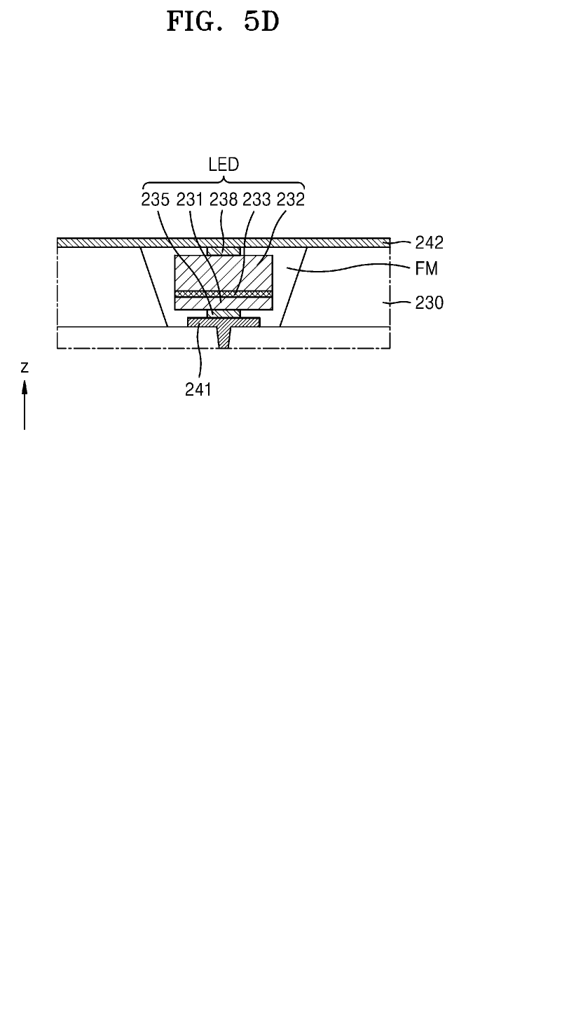

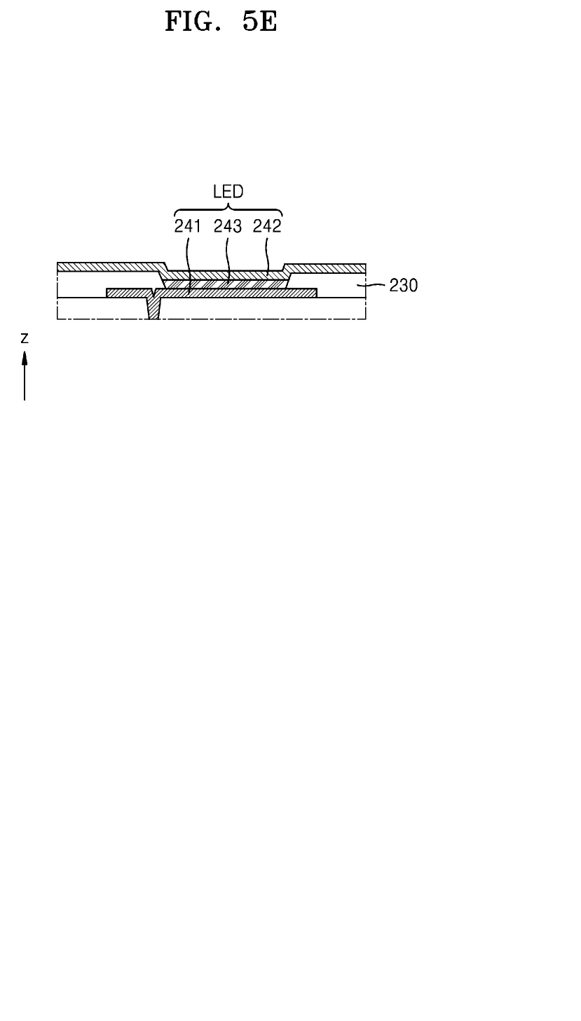

FIGS. 5A to 5E are respectively schematic cross-sectional views of an embodiment of light-emitting diodes of a display panel.

Referring to FIG. 5A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively and electrically connected to a first electrode pad 241 and a second electrode pad 242 arranged in the same layer. The second electrode pad 242 may be a portion of the second voltage line (VSSL in FIG. 4A) or a conductive layer electrically connected to the second voltage line (VSSL in FIG. 4A).

In some embodiments, the first semiconductor layer 231 may include a p-type semiconductor layer. The p-type semiconductor layer may include or consist of a semiconductor material having a composition formula of InₓAlyGa_{1-x-y}N (0≤x≤1, 0≤y≤1, 0≤x+y≤1), e.g., GaN, AlN, AlGaN, InGaN, InN, InAlGaN, or AlInN, and may be doped with p-type dopants such as Mg, Zn, Ca, Sr, or Ba.

The second semiconductor layer 232 may include an n-type semiconductor layer, for example. The n-type semiconductor layer may include or consist of a semiconductor material having a composition formula of InₓAlyGa_{1-x-y}N (0≤x≤1, 0≤y≤1, 0≤x+y≤1), e.g., GaN, AlN, AlGaN, InGaN, InN, InAlGaN, or AlInN, and may be doped with n-type dopants such as Si, Ge, or Sn.

The intermediate layer 233 may be a region where electrons and holes are recombined and may transition to a lower energy level as a result of the recombination, thereby generating light having a wavelength corresponding to the transition. The intermediate layer 233 may include a semiconductor material having a composition formula of InxAlyGa1-x-yN (0≤x≤1, 0≤y≤1, 0≤x+y≤1) and have a single quantum well structure or a Multi-Quantum Well (“MQW”) structure. Additionally, the intermediate layer 233 may have a quantum wire structure or a quantum dot structure.

FIG. 5A illustrates that the first semiconductor layer 231 includes a p-type semiconductor layer and the second semiconductor layer 232 includes an n-type semiconductor layer, but the disclosure is not limited thereto. In another embodiment, the first semiconductor layer 231 may include an n-type semiconductor layer and the second semiconductor layer 232 may include a p-type semiconductor layer.

FIG. 5A illustrates that the first electrode pad 241 and the second electrode pad 242 are arranged in the same layer, but the disclosure is not limited thereto. Referring to FIG. 5B, the first electrode pad 241 and the second electrode pad 242 may be arranged in different layers. In an embodiment, a bank layer 230, which defines an opening overlapping at least a portion of the first electrode pad 241, may be disposed on the first electrode pad 241, and the second electrode pad 242 may be disposed on an upper surface of the bank layer 230, for example. The structure of the light-emitting diode LED shown in FIG. 5B is the same as that described with reference to FIG. 5A.

In another embodiment, as shown in FIG. 5C, the second electrode pads 242 may be arranged on opposite sides with respect to the first electrode pad 241 in the cross-sectional view. The bank layer 230 may define an opening that overlaps at least a portion of the first electrode pad 241, and the second electrode pad 242 may be disposed around the opening of the bank layer 230. In some embodiments, in a plan view, the second electrode pad 242 may have a closed loop shape that surrounds an entirety of the opening of the bank layer 230 and/or the first electrode pad 241. The structure of the light-emitting diode LED shown in FIG. 5C is the same as that described with reference to FIG. 5A.

FIGS. 5A to 5C illustrate that the first electrode 235 and the second electrode 238 of the light-emitting diode LED are oriented in the same direction (e.g., a downward direction, -z direction), but the disclosure is not limited thereto. As shown in FIG. 5D, the first electrode 235 and the second electrode 238 of the light-emitting diode LED may be oriented in different directions.

The bank layer 230 may define an opening that exposes at least a portion of the first electrode pad 241, and the thickness of the bank layer 230 may be substantially the same as that of the light-emitting diode LED. The opening of the bank layer 230 may be filled with a filling material FM, and the second electrode pad 242 may be disposed on the upper surface of the bank layer 230 to be electrically connected to (e.g., to contact) the second electrode 238 of the light-emitting diode LED. The filling material FM may be an organic material having insulating properties.

FIGS. 5A to 5D illustrate that the light-emitting diode LED includes an inorganic light-emitting diode including an inorganic material, but the disclosure is not limited thereto. Referring to FIG. 5E, the light-emitting diode LED may include an organic light-emitting diode including an organic material. In an embodiment, the light-emitting diode LED may include the first electrode pad (or the first electrode) 241, an organic emission layer 243 that overlaps the first electrode pad 241 through the opening of the bank layer 230 disposed on the first electrode pad 241, and the second electrode pad (or the second electrode) 242 on the organic emission layer 243, for example. The second electrode pad 242 may be shared by the light-emitting diodes LED. In other words, the second electrode pad 242 of any one of the light-emitting diodes LED may be integrally connected to the second electrode pad 242 of another light-emitting diode LED.

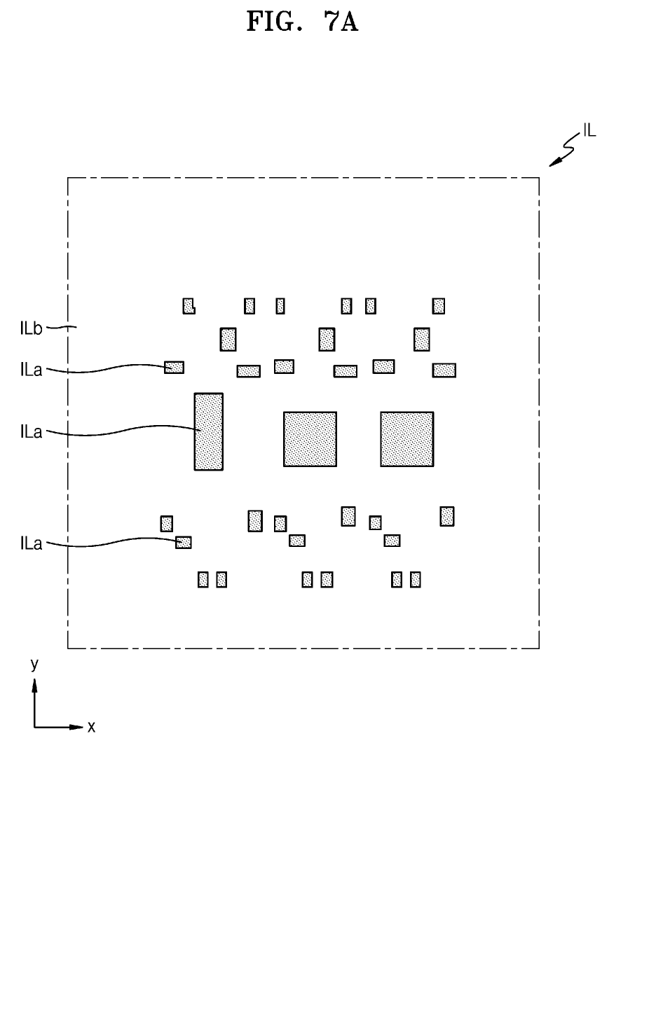

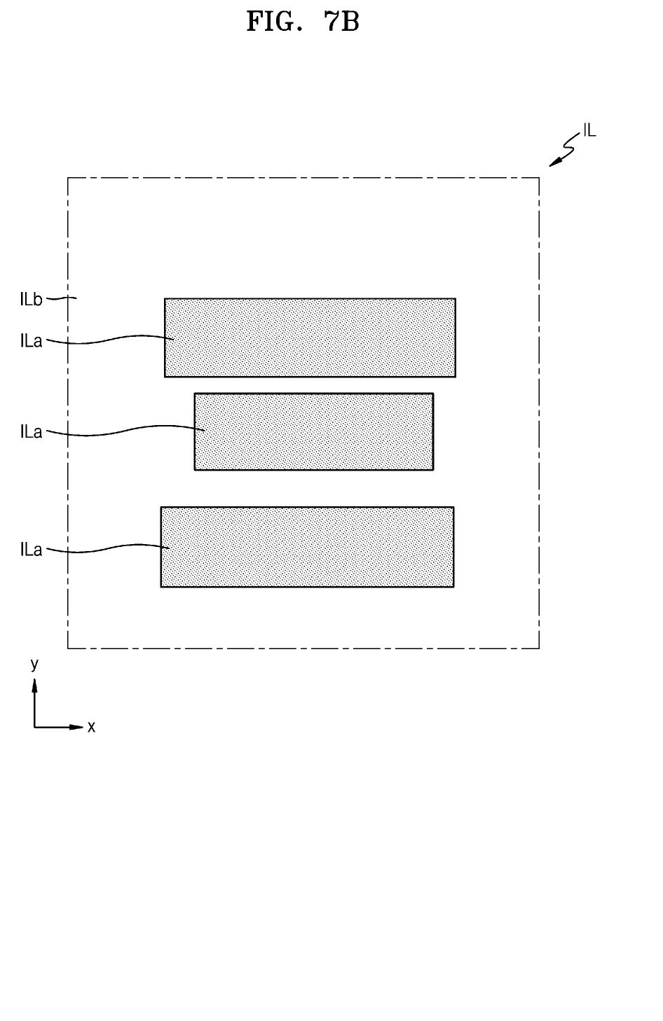

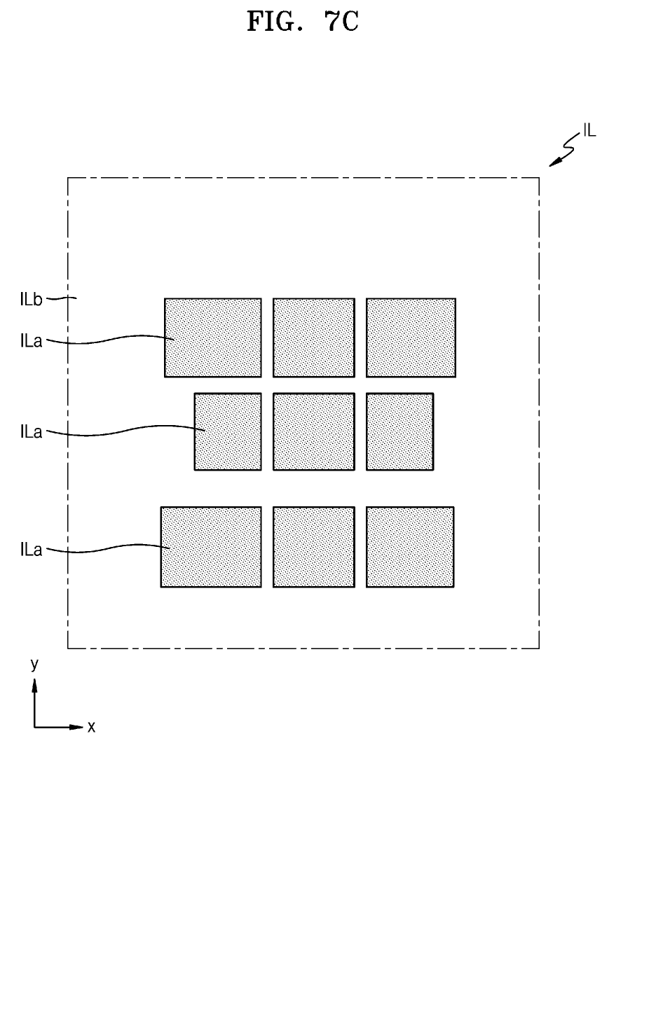

FIG. 6 is a schematic cross-sectional view showing an embodiment of a portion of the first area 11 of the display panel 10, and FIGS. 7A to 7C are schematic plan views of an embodiment of an insulating layer included in a display panel.

Referring to FIG. 6, in the first area 11 of the display panel 10, a pixel circuit layer 200 disposed on a substrate 100, light-emitting diodes LED1 to LED3 on the pixel circuit layer 200, and a protective layer 300 may be arranged.

In an embodiment, the substrate 100 may include polymer resin such as polyether sulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may include an elastomer. In an embodiment, the substrate 100 may include at least one of thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (“PDMS”), and Ecoflex^{TM} (Ecoflex^{TM} being a registered trademark of Smooth-On, Inc.), for example. The protective layer 300 may include an inorganic insulating layer, an alternating stack structure of inorganic insulating layers, or an elastomer.

The pixel circuit layer 200 may include pixel circuits PC and an insulating layer IL. The insulating layer IL may include a plurality of insulating layers, e.g., a first insulating layer IL1 to a sixth insulating layer IL6. Each pixel circuit PC may be electrically connected to its corresponding one of the light-emitting diodes LED1 to LED3. The first insulating layer IL1 to the fifth insulating layer IL5 may be arranged between conductive layers included in the pixel circuit PC. In an embodiment, the first insulating layer IL1 may be disposed between the substrate 100 and a semiconductor layer Act, for example. The second insulating layer IL2 may be disposed between the semiconductor layer Act and a gate electrode GE. The third insulating layer IL3 may be disposed between the first electrode CE1 and the second electrode CE2 of the storage capacitor. The fourth electrode IL4 may be disposed between the second electrode CE2 and a source or drain electrode SDE. The fifth insulating layer IL5 may be disposed between the source or drain electrode SDE and the light-emitting diodes LED1 to LED3. The sixth insulating layer IL6 may be disposed between the fifth insulating layer IL5 and the light-emitting diodes LED1 to LED3.

At least selected from the first insulating layer IL1 to the fifth insulating layer IL5, may include an inorganic material portion including an inorganic insulating material and an organic material portion including an organic insulating material.

In an embodiment, referring to FIGS. 7A to 7C, the insulating layer IL may include inorganic material portions ILa spaced apart from each other, and an organic material portion ILb. The insulating layer IL shown in FIGS. 7A to 7C may correspond to at least one of the first insulating layer IL1 to the fifth insulating layer IL5 described with reference to FIG. 6A. In other words, at least one of the first insulating layer IL1 to the fifth insulating layer IL5 may include the inorganic material portions ILa arranged apart from each other and the organic material portion ILb.

The width or area of one of the inorganic material portions ILa may be different from that of another inorganic material portion ILa. The inorganic material portions ILa may be arranged apart from each other and each be surrounded by the organic material portion ILb in a plan view.

As shown in FIGS. 7A to 7C, the inorganic material portions ILa may be arranged apart from each other in the first direction (e.g., the x direction) and the second direction (e.g., the y direction). As shown in FIG. 7B, the inorganic material portions ILa may be arranged apart from each other in the second direction (e.g., the y direction) or the first direction (e.g., the x direction).

FIGS. 7A to 7C illustrate that the shape of each inorganic material portion ILa is substantially a rectangle, but the shape is not limited thereto. The shape of each inorganic material portion ILa may be modified into various forms, e.g., a polygon, an oval, a circle, or an irregular shape.

The inorganic material portion ILa may include an inorganic insulating material, such as silicon oxide, silicon nitride, or silicon oxynitride. The organic material portion ILb may include an organic insulating material, such as acryl, benzocyclobutene (“BCB”), polyimide, or hexamethyldisiloxane (“HMDSO”).

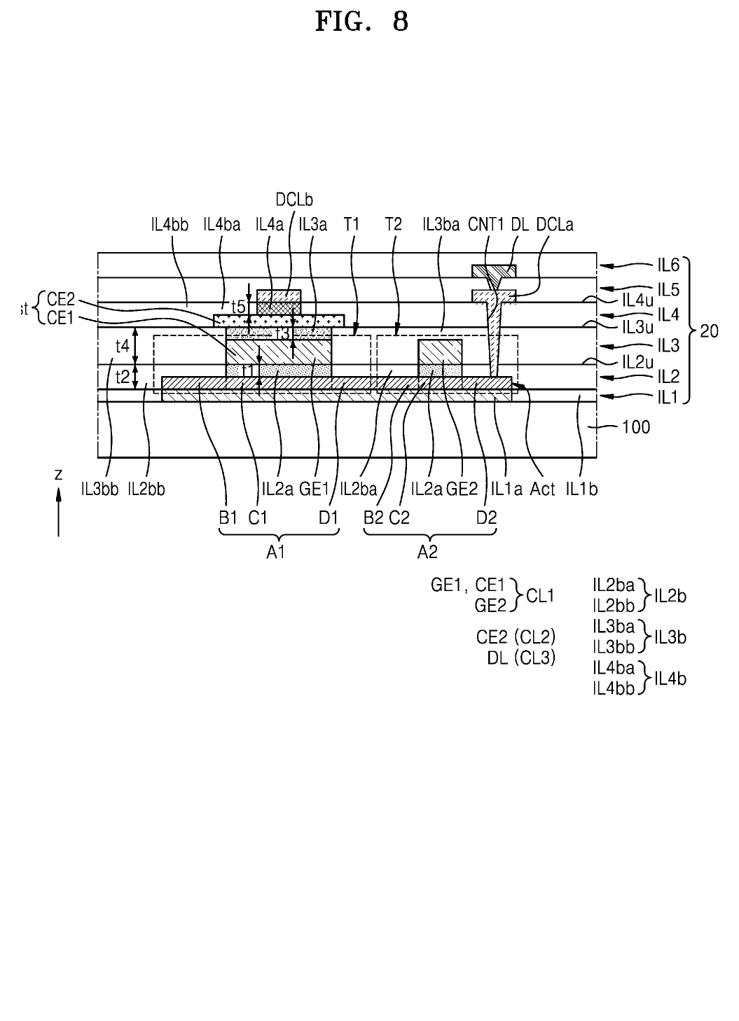

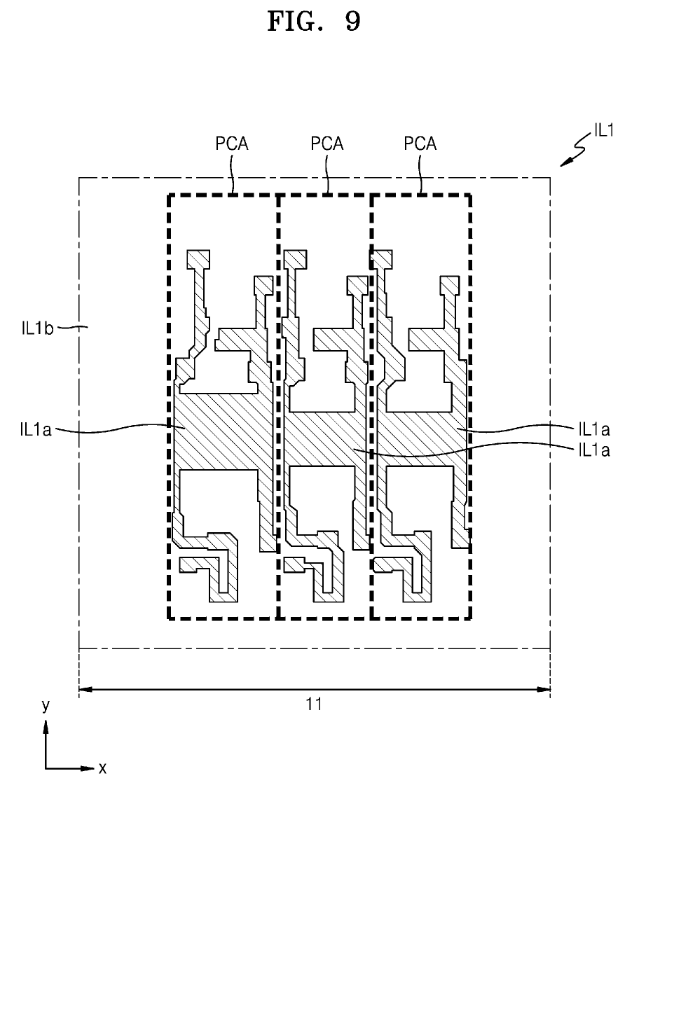

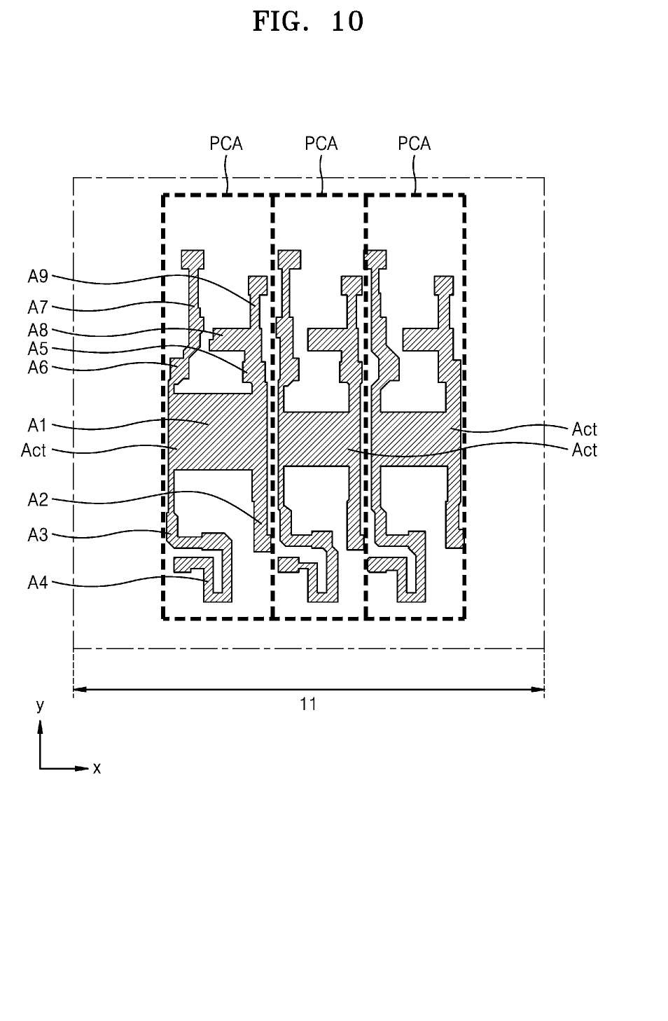

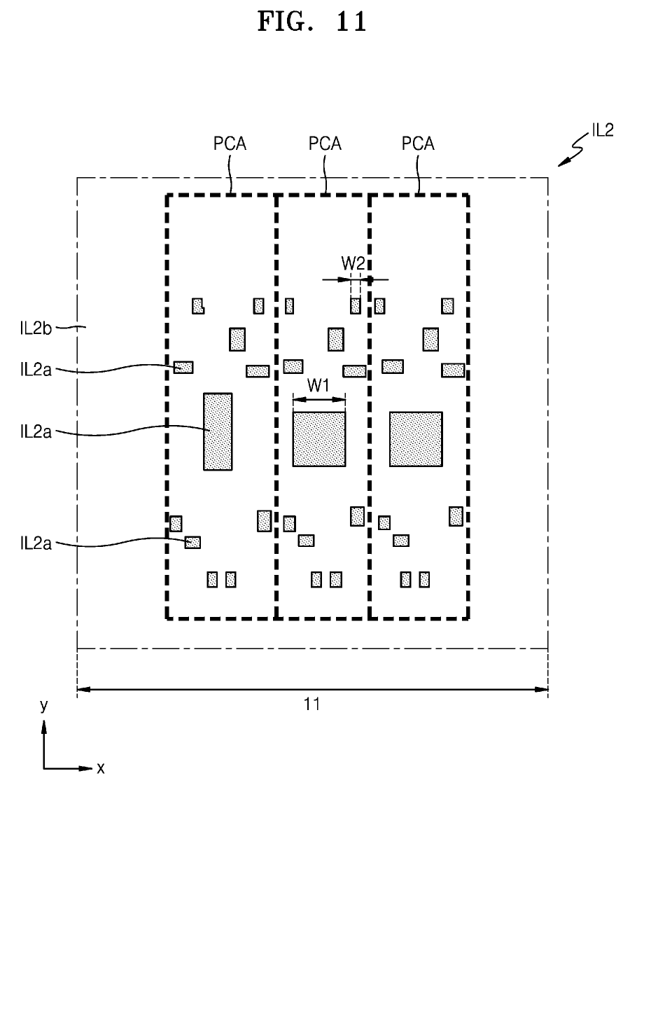

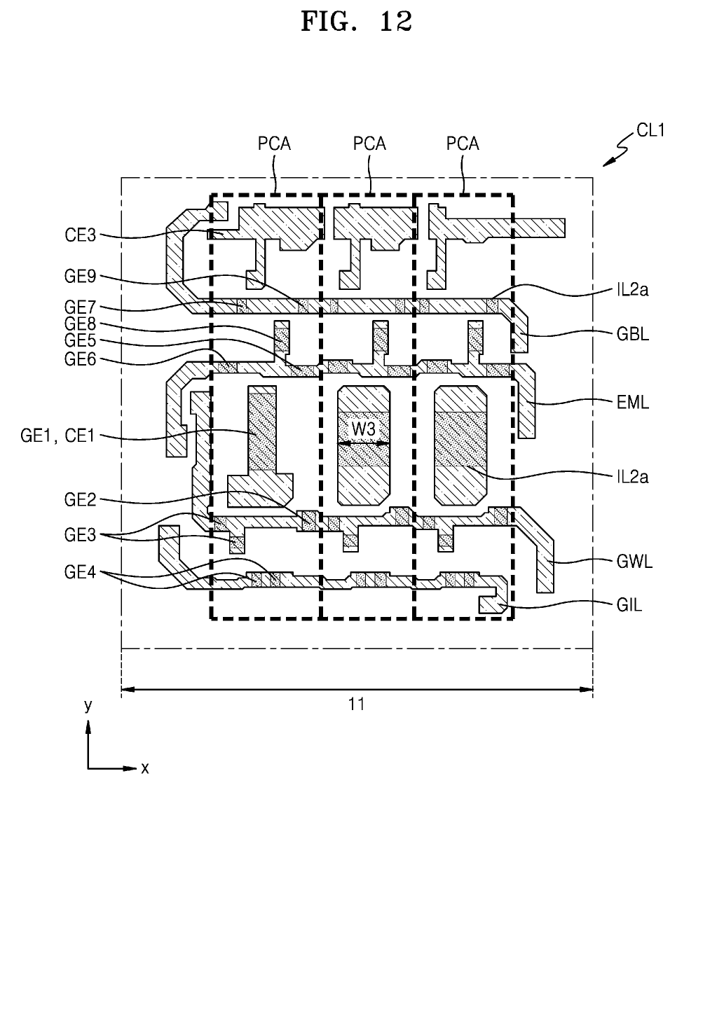

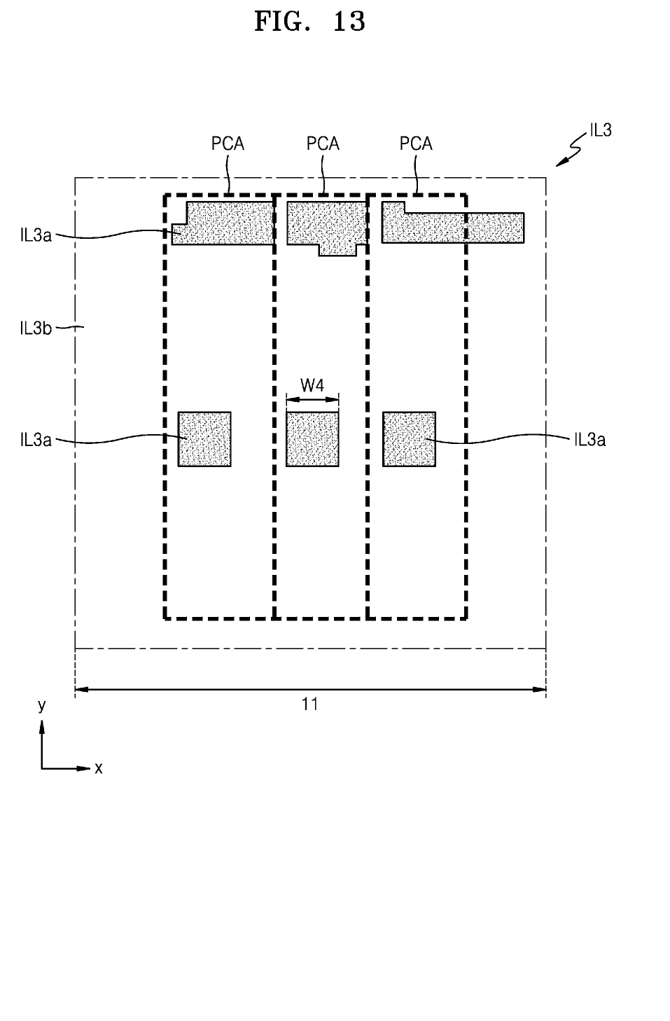

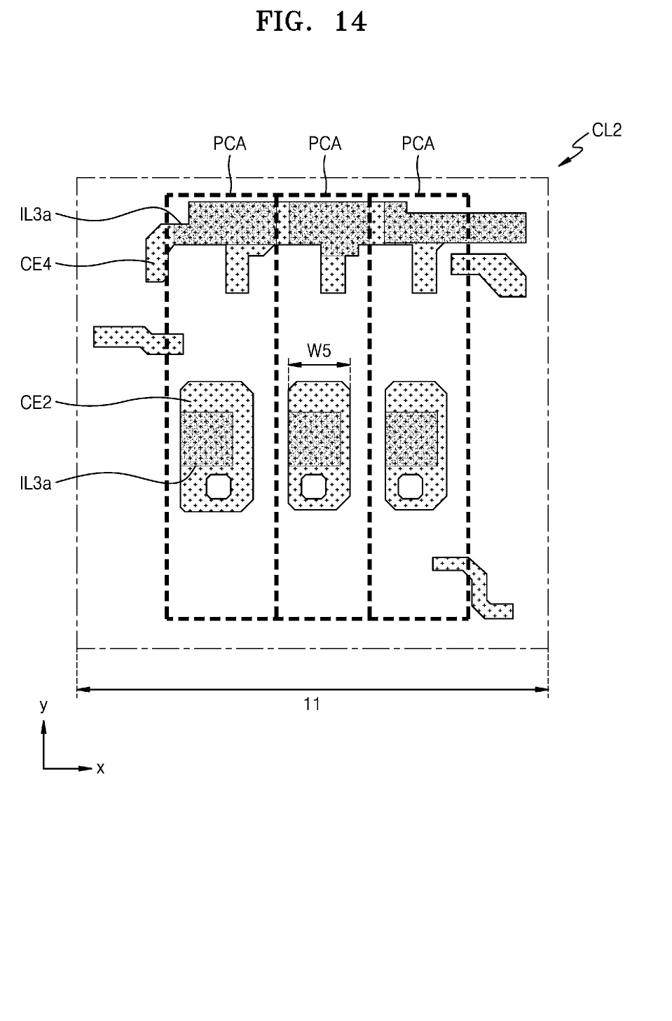

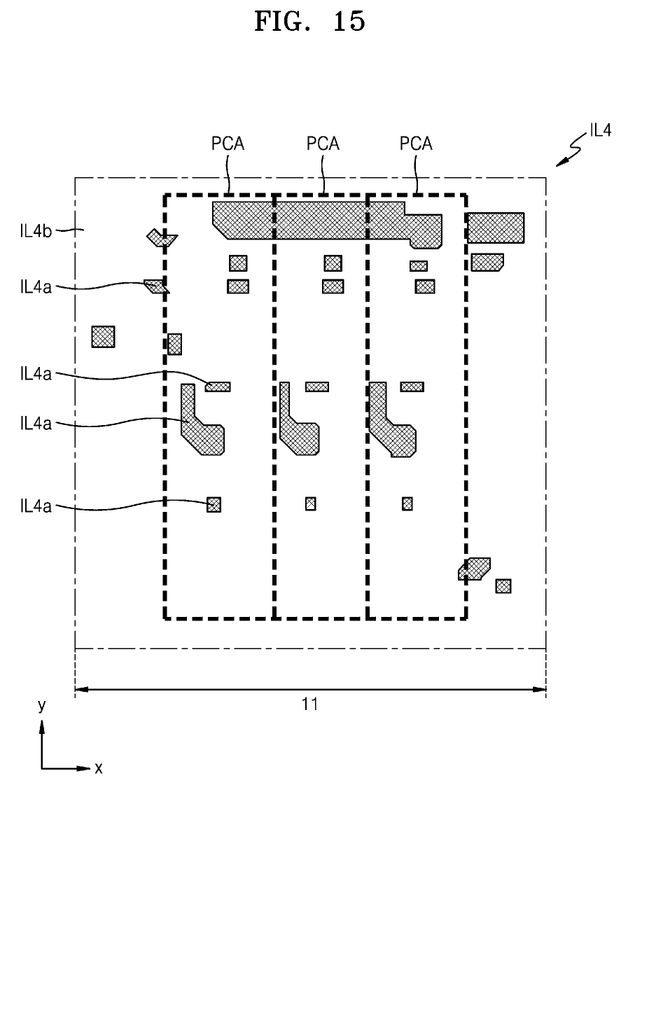

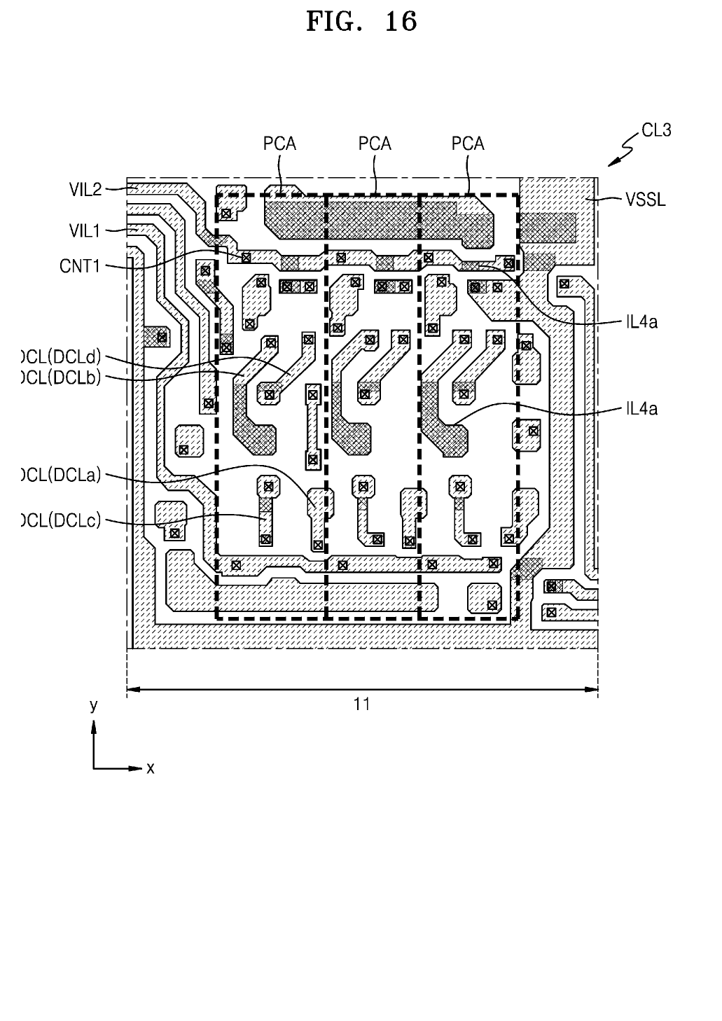

FIG. 8 is a cross-sectional view of an embodiment of a portion of the pixel circuit layer 200 of the display panel, FIG. 9 is a plan view of an embodiment of the first insulating layer IL1 of the display panel, FIG. 10 is a plan view of an embodiment of the semiconductor layer Act of the display panel, FIG. 11 is a plan view of an embodiment of the second insulating layer IL2 of the display panel, FIG. 12 is a plan view of an embodiment of a first conductive layer CL1 of the display panel, FIG. 13 is a plan view of an embodiment of the third insulating layer IL3 of the display panel, FIG. 14 is a plan view of an embodiment of a second conductive layer CL2 of the display panel, FIG. 15 is a plan view of an embodiment of the fourth insulating layer IL4 of the display panel, and FIG. 16 is a plan view of a third conductive layer CL3 of the display panel. FIGS. 9 to 16 illustrate planar structures of respective layers in pixel circuit areas PCA corresponding to three pixel circuits that may be arranged in the first area 11, and FIG. 8 illustrates the first transistor T1, the storage capacitor Cst, and the second transistor T2 which are arranged in one pixel circuit area PCA (refer to FIG. 9 and other drawing figures).

Referring to FIGS. 8 and 9, the first insulating layer IL1 may be disposed on the substrate 100. The first insulating layer IL1 may include first inorganic material portions IL1a including inorganic insulating materials and a first organic material portion IL1b including an organic insulating material. In a plan view, the first organic material portion IL1b may surround an entirety of each first inorganic material portion IL1a.

The first inorganic material portion IL1a may include an inorganic insulating material, such as silicon oxide, silicon nitride, or silicon oxynitride. The first organic material portion IL1b may include an organic insulating material, such as acryl, BCB, polyimide, or HMDSO.

The first inorganic material portions IL1a may be spaced apart from each other. In an embodiment, FIG. 9 illustrates that the first inorganic material portions IL1a are respectively arranged in the pixel circuit areas PCA and spaced apart from each other.

Referring to FIG. 9, in an embodiment, the shape of the first inorganic material portion IL1a may be the same as that of the semiconductor layer Act described below with reference to FIG. 10. The area (or width) of the first inorganic material portion IL1a may be the same as that of the semiconductor layer Act described below with reference to FIG. 10.

In an embodiment, the shape of the first inorganic material portion IL1a may be different from that of the semiconductor layer Act described below with reference to FIG. 10. The area (or width) of the first inorganic material portion IL1a may be greater than that of the semiconductor layer Act described below with reference to FIG. 10.

Referring to FIGS. 8, 9, and 10, the semiconductor layer Act may be disposed on the first insulating layer IL1. The semiconductor layer Act disposed in each pixel circuit area PCA may have a serpentine shape, as shown in FIG. 10.

The semiconductor layer Act shown in FIG. 10 may be disposed on the first insulating layer IL1 described with reference to FIG. 9. In an embodiment, referring to FIGS. 8 to 10, the semiconductor layer Act in each pixel circuit area PCA may cover an entirety of the first inorganic material portion IL1a between the semiconductor layer Act and the substrate (100 in FIG. 8). In other words, the entirety of the bottom surface of the semiconductor layer Act may overlap (e.g., directly contact) the upper surface of the first inorganic material portion IL1a.

The semiconductor layer Act in each pixel circuit area PCA may include semiconductor layers of transistors corresponding to pixel circuits. In other words, a portion of the semiconductor layer Act may correspond to the semiconductor layer of each transistor. In an embodiment, FIG. 10 illustrates that the semiconductor layer Act includes a first semiconductor layer A1 to a ninth semiconductor layer A9 of the first transistor T1 to the ninth transistor T9 described with reference to FIG. 4C. The first semiconductor layer A1 to the ninth semiconductor layer A9 correspond to the semiconductor layers of the first transistor T1 to the ninth transistor T9, respectively. FIG. 8 illustrates the first semiconductor layer A1 and the second semiconductor layer A2 of the semiconductor layer Act.

Referring to FIG. 8, the first semiconductor layer A1 may include a channel area C1 and source and drain areas B1 and D1 arranged on opposite sides of the channel area C1, and the second semiconductor layer A2 may include a channel area C2 and source and drain areas B2 and D2 arranged on opposite sides of the channel area C2. The first semiconductor layer A1 may be integrally connected to the second semiconductor layer A2. FIG. 8 illustrates the channel areas and source and drain areas of the first semiconductor layer A1 and the second semiconductor layer A2, but the disclosure is not limited thereto. Each of the third semiconductor layer A3 to the ninth semiconductor layer A9 includes a channel area, a source area, and a drain area.

The semiconductor layer Act may include polysilicon. In an alternative embodiment, the semiconductor layer Act may include amorphous silicon, an oxide semiconductor, an organic semiconductor, or the like.

Referring to FIGS. 8, 10, and 11, the second insulating layer IL2 may be disposed on the semiconductor layer Act. The second insulating layer IL2 may include second inorganic material portions IL2a including inorganic insulating materials and a second organic material portion IL2b disposed around the second inorganic material portions IL2a and including an organic insulating material. In a plan view, the second organic material portion IL2b may surround an entirety of each of the second inorganic material portions IL2a.

The second inorganic material portion IL2a may include an inorganic insulating material, such as silicon oxide, silicon nitride, or silicon oxynitride. The second organic material portion IL2b may include an organic insulating material, such as acryl, BCB, polyimide, or HMDSO. In a plan view, the second organic material portion IL2b may surround an entirety of each of the second inorganic material portions IL2a.

The upper surface of the second inorganic material portion IL2a and the upper surface of the second organic material portion IL2b may be in substantially the same plane. In an embodiment, the upper surface of the second inorganic material portion IL2a and the upper surface of the second organic material portion IL2b may be disposed on the upper surface (IL2u in FIG. 8) of the second insulating layer IL2, for example. In an embodiment, as shown in FIG. 8, a first vertical distance from the upper surface of the substrate 100 to the upper surface of the second inorganic material portion IL2a may be the same as a second vertical distance from the upper surface of the substrate 100 to the upper surface of the second organic material portion IL2b.

The second inorganic material portions IL2a may be respectively arranged in the pixel circuit areas PCA. The second inorganic material portions IL2a may be spaced apart from each other in the same pixel circuit area PCA.

The second insulating layer IL2 shown in FIG. 11 may be disposed on the semiconductor layer Act described with reference to FIG. 10. In an embodiment, referring to FIGS. 8, 10, and 11, the second inorganic material portions IL2a may be arranged to overlap the semiconductor layer (Act in FIG. 10) disposed in their corresponding pixel circuit areas PCA. A portion of the semiconductor layer (Act in FIG. 10) overlapping the second inorganic material portion IL2a may correspond to the channel area of each of the first semiconductor layer A1 to the ninth semiconductor layer A9. In relation to this, FIG. 8 illustrates that one of the second inorganic material portions IL2a overlaps the channel area C1 of the first semiconductor layer A1, and another overlaps the channel area C2 of the second semiconductor layer A2.

The width of one of the second inorganic material portions IL2a arranged in each pixel circuit area PCA may differ from that of another. In an embodiment, the width W1 of one of the second inorganic material portions IL2a shown in FIG. 11 may be greater than the width W2 of another second inorganic material portion IL2a, for example. In an embodiment, the second inorganic material portion IL2a, which overlaps the first semiconductor layer (A1 in FIG. 10) among the second inorganic material portions IL2a arranged in each pixel circuit area PCA, may have the greatest width W1 among remaining (the other) second inorganic material portions IL2a arranged in the same pixel circuit area PCA.

As shown in FIG. 8, the second organic material portion (also referred to as first organic material portion when firstly introduced) IL2b may include a 2-1^{st} organic material portion (also referred to as 1-1^{st} organic material portion) IL2ba that overlaps the semiconductor layer Act and a 2-2^{nd} organic material portion (also referred to as 1-2^{nd} organic material portion) IL2bb that does not overlap the semiconductor layer Act. The thickness t1 of the second inorganic material portion IL2a that overlaps the semiconductor layer Act may be less than the thickness t2 of the 2-2^{nd} organic material portion IL2bb that does not overlap the semiconductor layer Act. The thickness of the 2-1^{st} organic material portion IL2ba may be less than the thickness t2 of the 2-2^{nd} organic material portion IL2bb. The thickness of the 2-1^{st} organic material portion IL2ba may be substantially the same as the thickness t1 of the second inorganic material portion IL2a.

Referring to FIGS. 8, 11, and 12, the first conductive layer CL1 may be disposed on the second insulating layer IL2. For better understanding, FIG. 12 illustrates the first conductive layer CL1 together with the second inorganic material portions IL2a disposed in each pixel circuit area PCA shown in FIG. 11.

The first conductive layer CL1 may include a conductive material including Mo, Al, Cu, or Ti and may be a layer or layers including the above material.

The first conductive layer CL1 may include a first gate electrode GE1 to a ninth gate electrode GE9 corresponding to the pixel circuit areas PCA, respectively. The first gate electrode GE1 to the ninth gate electrode GE9 may each overlap the second inorganic material portion IL2a of the second insulating layer (IL2 in FIG. 11) disposed thereunder. The first gate electrode GE1 to the ninth gate electrode GE9 may each be in direct contact with the upper surface of the second inorganic material portion IL2a of the second insulating layer (IL2 in FIG. 11).

The width W3 of the first gate electrode GE1 disposed in each pixel circuit area PCA may be substantially the same as the width (W1 in FIG. 11) of the second inorganic material portion IL2a overlapping the first gate electrode GE1. The width W3 of the first gate electrode GE1 disposed in each pixel circuit area PCA may be less or greater than the width (W1 in FIG. 11) of the second inorganic material portion IL2a overlapping the first gate electrode GE1.

The first gate electrode GE1 may be integrally connected to the first electrode CE1 of the storage capacitor (Cst in FIG. 8). In other words, the first gate electrode GE1 may perform the function of the first electrode CE1 of the storage capacitor (Cst in FIG. 8), and the first electrode CE1 may perform the function of the first gate electrode GE1.

When the first gate electrode GE1 is the first electrode CE1, the first electrode CE1 of the storage capacitor Cst may overlap the second inorganic material portion IL2a of the second insulating layer IL2 that overlaps the channel area C1 of the first semiconductor layer A1. The first gate electrode GE1 and/or the first electrode CE1 may directly contact the upper surface of the second inorganic material portion IL2a. In an embodiment, the width (W3 in FIG. 11) of the first electrode CE1 may be substantially the same as the width (W1 in FIG. 11) of the second inorganic material portion IL2a that overlaps the first electrode CE1. In an embodiment, the width W3 of the first electrode CE1 may be less or greater than the width (W1 in FIG. 11) of the second inorganic material portion IL2a that overlaps the first electrode CE1.

The scan signal line GWL may extend in the first direction (e.g., the x direction) to cross the pixel circuit areas PCA in the first area 11. The scan signal line GWL may include the second gate electrode GE2 and the third gate electrode GE3 of each pixel circuit area PCA.

The initialization control line GIL may extend in the first direction (e.g., the x direction) to cross the pixel circuit areas PCA in the first area 11. The initialization control line GIL may include the fourth gate electrode GE4 of each pixel circuit area PCA.

The emission control line EML may extend in the first direction (e.g., the x direction) to cross the pixel circuit areas PCA in the first area 11. The emission control line EML may be disposed on the opposite side of the scan signal line GWL with the first gate electrode GE1 therebetween. The scan signal line GWL may include the fifth gate electrode GE5, the sixth gate electrode GE6, and the eighth gate electrode GE8 of each pixel circuit area PCA.

The bypass control line GBL may extend in the first direction (e.g., the x direction) to cross the pixel circuit areas PCA in the first area 11. The bypass control line GBL may include the seventh gate electrode GE7 and the ninth gate electrode GE9 of each pixel circuit area PCA.

In an embodiment, the first conductive layer CL1 may include an electrode (hereinafter, also referred to as the third electrode CE3) of the auxiliary capacitor (Ca in FIG. 4C). The third electrode CE3 may be disposed in each pixel circuit area PCA.

Referring to FIGS. 8, 12, and 13, the third insulating layer IL3 may be disposed on the first conductive layer CL1. The third insulating layer IL3 may include third inorganic material portions IL3a and a third organic material portion IL3b around the third inorganic material portions IL3a. In a plan view, the third organic material portion IL3b may surround an entirety of each of the third inorganic material portions IL3a.

The third inorganic material portion IL3a may include an inorganic insulating material, such as silicon oxide, silicon nitride, or silicon oxynitride. The third organic material portion IL3b may include an organic insulating material, such as acryl, BCB, polyimide, or HMDSO.

The third insulating layer IL3 shown in FIG. 13 may be disposed on the first conductive layer CL1 described with reference to FIG. 12. One of the third inorganic material portions IL3a arranged in each pixel circuit area PCA shown in FIG. 13 may overlap the first gate electrode (GE1 in FIG. 12) and/or the first electrode (CE1 in FIG. 12), and another thereof may overlap the third electrode (CE3 in FIG. 12).

The upper surface of the third inorganic material portion IL3a and the upper surface of the third organic material portion IL3b may be in substantially the same plane. In an embodiment, the upper surface of the third inorganic material portion IL3a and the upper surface of the third organic material portion IL3b may be disposed on the upper surface (IL3u in FIG. 8) of the third insulating layer IL3, for example. In an embodiment, as shown in FIG. 8, a third vertical distance from the upper surface of the substrate 100 to the upper surface of the third inorganic material portion IL3a may be the same as a fourth vertical distance from the upper surface of the substrate 100 to the upper surface of the third organic material portion IL3b.

The third inorganic material portions IL3a may be arranged in each pixel circuit area PCA. The second inorganic material portions IL2a may be spaced apart from each other in the same pixel circuit area PCA. In an embodiment, one of the second inorganic material portions IL2a in the same pixel circuit area PCA may overlap the first electrode (CE1 in FIG. 12), and another may overlap the third electrode (CE3 in FIG. 12).

In an embodiment, the width (W4 in FIG. 13) of the third inorganic material portion IL3a that overlaps the first electrode CE1 shown in FIGS. 8 and 12 may be the same as or greater than the width (W3 in FIG. 12) of the first electrode CE1. In an embodiment, the width (W4 in FIG. 13) of the third inorganic material portion IL3a that overlaps the first electrode CE1 may be less than the width (W3 in FIG. 12) of the first electrode CE1. The third inorganic material portion IL3a may overlap the second inorganic material portion IL2a.

Referring to FIG. 8, the third organic material portion IL3b may include a 3-1^{st} organic material portion IL3ba that overlaps the first conductive layer (CL1 in FIG. 12) and a 3-2^{nd} organic material portion IL3bb that does not overlap the first conductive layer (CL1 in FIG. 12). In an embodiment, the 3-1^{st} organic material portion IL3ba may overlap gate electrodes of switching transistors, e.g., the second gate electrode GE2 of the second transistor T2.

The thickness t3 of the third inorganic material portion IL3a overlapping the first conductive layer (CL1 in FIG. 12), e.g., the third inorganic material portion IL3a overlapping the first electrode CE1, may be less than the thickness t4 of the 3-2^{nd} organic material portion IL3bb that does not overlap the first conductive layer (CL1 in FIG. 12). The thickness of the 3-1^{st} organic material portion IL3ba may be less than the thickness t4 of the 3-2^{nd} organic material portion IL3bb. The thickness of the 3-1^{st} organic material portion IL3ba may be substantially the same as the thickness t3 of the third inorganic material portion IL3a. In an embodiment, as shown in FIG. 8, the thickness of the 3-1^{st} organic material portion IL3ba, which overlaps the second gate electrode GE2, may be substantially the same as the thickness t3 of the third inorganic material portion IL3a, for example.

Referring to FIGS. 8, 13, and 14, the second conductive layer CL2 may be disposed on the third insulating layer IL3. For better understanding, FIG. 14 illustrates the second conductive layer CL2 together with the third inorganic material portions IL3a arranged in each pixel circuit area PCA shown in FIG. 13.

The second conductive layer CL2 may include a conductive material including Mo, Al, Cu, or Ti and may be a layer or layers including the above material.

The second conductive layer CL2 may include the second electrode CE2 and the fourth electrode CE4 that correspond to the pixel circuit areas PCA, respectively. The second electrode CE2 and the fourth electrode CE4 may respectively overlap the third inorganic material portions IL3a of the third insulating layer (IL3 in FIG. 13) that are arranged thereunder. The second electrode CE2 and the fourth electrode CE4 may directly contact the upper surfaces of the third inorganic material portions IL3a of the third insulating layer (IL3 in FIG. 13) that are arranged thereunder, respectively.

In an embodiment, the width W5 of the second electrode CE2 in each pixel circuit area PCA may be the same as or greater than the width (W4 in FIG. 13) of the third inorganic material portion IL3a that overlaps the second electrode CE2. In an embodiment, the width W5 of the second electrode CE2 may be less than the width (W4 in FIG. 13) of the third inorganic material portion IL3a that overlaps the second electrode CE2.

Referring to FIGS. 8, 14, and 15, the fourth insulating layer IL4 may be disposed on the second conductive layer CL2. The fourth insulating layer IL4 may include fourth inorganic material portions IL4a that overlap the second conductive layer CL2 and a fourth organic material portion IL4b around the fourth inorganic material portions IL4a. In a plan view, the fourth organic material portion IL4b may surround an entirety of each of the fourth inorganic material portions IL4a.

The fourth inorganic material portion IL4a may include an inorganic insulating material, such as silicon oxide, silicon nitride, or silicon oxynitride. The fourth organic material portion IL4b may include an organic insulating material, such as acryl, BCB, polyimide, or HMDSO.

The upper surface of the fourth inorganic material portion IL4a and the upper surface of the fourth organic material portion IL4b may be in substantially the same plane. In an embodiment, the upper surface of the fourth inorganic material portion IL4a and the upper surface of the fourth organic material portion IL4b may be disposed on the upper surface (IL4u in FIG. 8) of the fourth insulating layer IL4, for example. In an embodiment, as shown in FIG. 8, a fifth vertical distance from the upper surface of the substrate 100 to the upper surface of the fourth inorganic material portion IL4a may be the same as a fourth vertical distance from the upper surface of the substrate 100 to the upper surface of the fourth organic material portion IL4b.

The fourth inorganic material portions IL4a may be arranged in each pixel circuit area PCA. The fourth inorganic material portions IL4a may be spaced apart from each other in the same pixel circuit area PCA.

The fourth organic material portion IL4b may include a 4-1^{st} organic material portion IL4ba that overlaps the second conductive layer (CL2 in FIG. 14) and a 4-2^{nd} organic material portion IL4bb that does not overlap the second conductive layer CL2.

The thickness t5 of the fourth inorganic material portion IL4a overlapping the second conductive layer (CL2 in FIG. 14), e.g., the fourth inorganic material portion IL4a overlapping the second electrode CE2, may be less than the thickness t6 of the 4-2^{nd} organic material portion IL4bb that does not overlap the second conductive layer (CL2 in FIG. 14). The thickness of the 4-1^{st} organic material portion IL4ba may be substantially the same as the thickness t5 of the fourth inorganic material portion IL4a.

Referring to FIGS. 8, 15, and 16, the third conductive layer CL3 may be arranged on the fourth insulating layer IL4. For better understanding, FIG. 16 illustrates the third conductive layer CL3 together with the fourth inorganic material portions IL4a disposed in each pixel circuit area PCA shown in FIG. 15.

The third conductive layer CL3 may include a conductive material including Mo, Al, Cu, or Ti and may be a layer or layers including the above material.

The third conductive layer CL3 may include connectors DCL that may be electrically connected to the semiconductor layer (Act in FIG. 10), the first gate electrode (GE1 in FIG. 12), the first electrode (CE1 in FIG. 12), and/or the second electrode (CE2 in FIG. 14). In an embodiment, as shown in FIG. 16, the third conductive layer CL3 may include a first initialization voltage line VIL1, a second initialization voltage line VIL2, a second voltage line VSSL, and the connectors DCL. The first initialization voltage line VIL1, the second initialization voltage line VIL2, the second voltage line VSSL, and the connectors DCL may overlap the fourth inorganic material portions IL4a of the fourth insulating layer IL4 that are arranged thereunder, respectively. The connectors DCL shown in FIG. 16 may include a first connector DCLa connected to the second semiconductor layer (A2 in FIG. 10), a second connector DCLb overlapping the second electrode (CE2 in FIG. 14), a third connector DCLc electrically connecting the first gate electrode (GE1 in FIG. 12) to the third semiconductor layer (A3 in FIG. 10), a fourth connector DCLd electrically connecting the second electrode (CE2 in FIG. 14) to the fifth semiconductor layer (A5 in FIG. 10) and the eighth semiconductor layer (A8 in FIG. 10). Each of the first connector DCLa to the fourth connector DCLd may overlap the fourth inorganic material portion IL4a.

The connectors DCL may be electrically connected to the semiconductor layer, the first electrode (CE1 in FIG. 12), and/or the second electrode (CE2 in FIG. 14). In an embodiment, FIG. 8 illustrates the first connector DCLa electrically connected to the second semiconductor layer A2 and the second connector DCLb overlapping the second electrode CE2.

Referring to FIG. 8, the first connector DCLa may electrically connect the second semiconductor layer A2 to the data line DL disposed on the fifth insulating layer IL5. The first connector DCLa may directly contact the upper surface of the second semiconductor layer A2 through a first contact hole CNT1 penetrating insulating layers (e.g., the second insulating layer IL2 to the fourth insulating layer IL4) between the second semiconductor layer A2 and the first connector DCLa. In this case, the first contact hole CNT1 may pass through each of the second organic material portion IL2b, the third organic material portion IL3b, and the fourth organic material portion IL4b, which are respectively included in the second insulating layer IL2, the third insulating layer IL3, and the fourth insulating layer IL4. In other words, the first contact hole CNT1 may not overlap or pass through the second organic material portion IL2b, the third organic material portion IL3b, and the fourth organic material portion IL4b, which are respectively included in the second insulating layer IL2, the third insulating layer IL3, and the fourth insulating layer IL4.

The sixth insulating layer IL6 may be disposed on the data line DL. The sixth insulating layer IL6 may include an organic insulating material. FIG. 8 illustrates that the data line DL and the first connector DCLa are arranged in different layers, but the disclosure is not limited thereto. In another embodiment, the first connector DCLa may be disposed in the same layer as the data line DL and may be a portion of the data line DL.

By the embodiments described with reference to FIGS. 8 to 16, as at least one of the insulating layers in the first area 11, e.g., the first insulating layer IL1 to the fifth insulating layer IL5, includes patterned inorganic material portions and an organic material layer surrounding the inorganic material portions, the operation characteristics (e.g., operation characteristics of transistors and storage capacitors) of a pixel circuit may be secured while preventing damage to the insulating layers and layers around the insulating layers, the damage being caused by stress applied to the display panel when the display panel is stretched. Therefore, a display panel that may produce high-quality images and is stretchable may be provided.

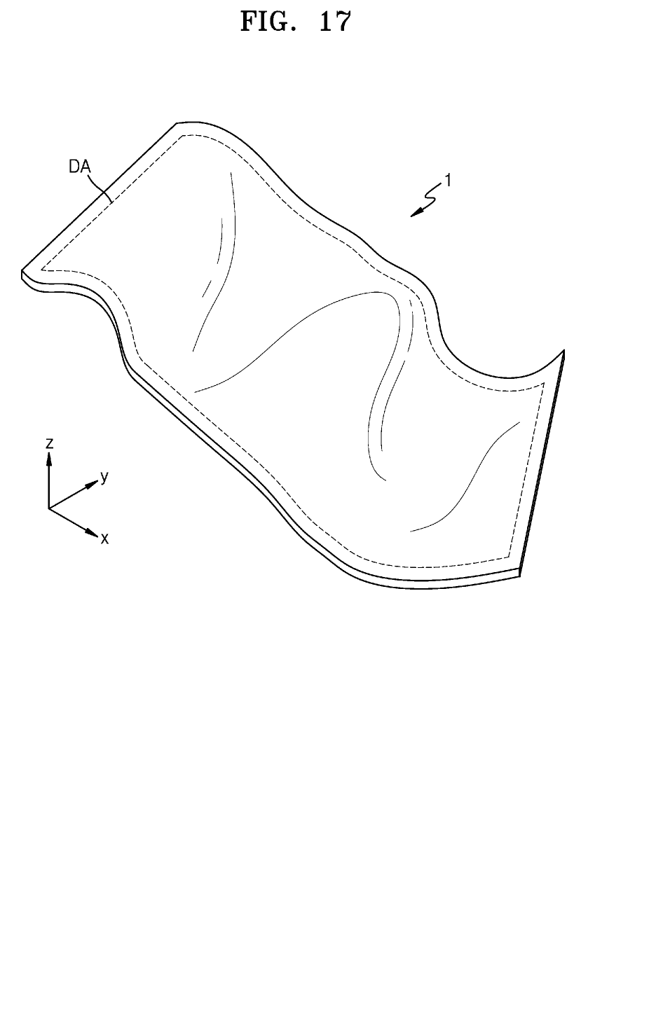

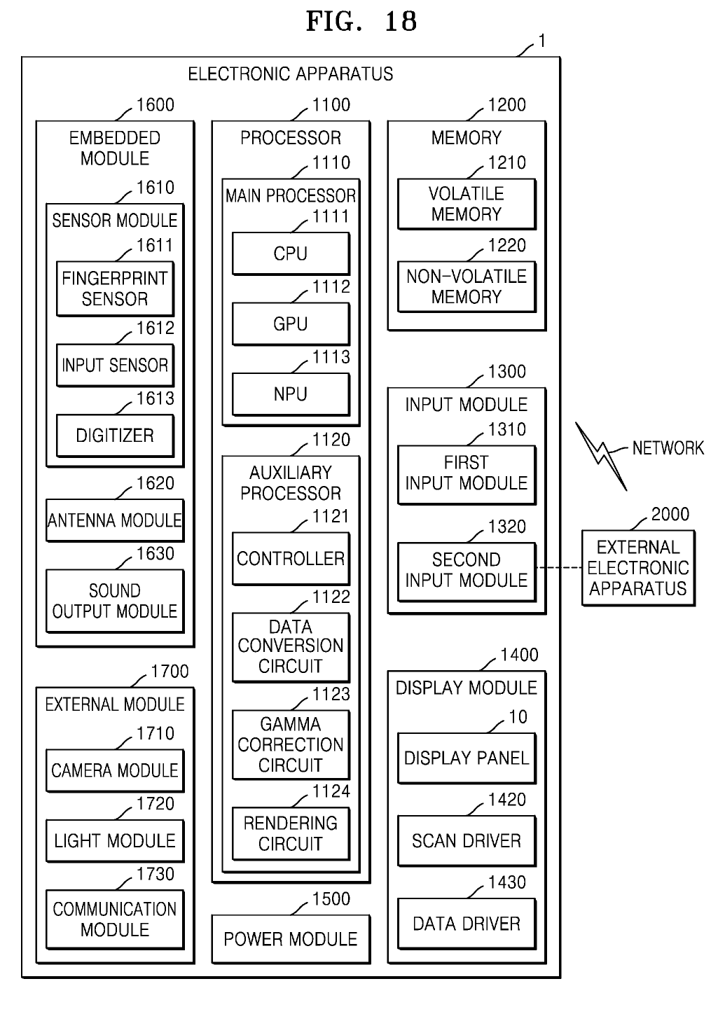

FIG. 17 is a schematic perspective view of an embodiment of an electronic apparatus 1 including a display panel, and FIG. 18 is a block diagram of an embodiment of the electronic apparatus 1 including the display panel 10.

Referring to FIG. 17, the electronic apparatus 1 may undergo free three-dimensional deformation and provide a three-dimensional image plane through the display area DA. The free three-dimensional deformation of the electronic apparatus 1 is distinguished from the operation of an electronic apparatus including a rollable display panel where only a rolled portion of a display area is visible to a user and then the entirety of the display area becomes visible because the rolled portion is unrolled (or the entirety of the unfolded display area is initially visible and then only a portion of the display area is visible to the user as the display area is rolled). The electronic apparatus 1 in embodiments may undergo deformation, such as an increase in the area of the entirety of the display area DA, followed by a decrease, as the electronic apparatus 1 is deformed in the x direction, y direction, and/or z direction.

Referring to FIG. 18, the electronic apparatus 1 may include a processor 1100, a memory 1200, an input module 1300, a display module 1400, a power module 1500, an embedded module 1600, and an external module 1700. In an embodiment, at least one of the above-described components of the electronic apparatus 1 may be omitted, or one or more additional components may be added. In an embodiment, some of the aforementioned components (e.g., the embedded module 1600) may be integrated into another component (e.g., the display module 1400).

The processor 1100 may execute software to control at least one component (e.g., a hardware component or a software component) of the electronic apparatus 1 connected to the processor 1100 and may perform various data processing tasks or operations. In an embodiment, as at least part of the data processing tasks or operations, the processor 1100 may store, in volatile memory 1210, commands or data received from other components (e.g., the input module 1300, a sensor module 1610, or a communication module 1730), process the commands or data stored in the volatile memory 1210, and store resulting data in non-volatile memory 1220.

The processor 1100 may include a main processor 1110 and an auxiliary processor 1120. The main processor 1110 may include at least one of a Central Processing Unit (“CPU”) 1111 and an Application Processor (“AP”). The main processor 1110 may further include at least one of a Graphics Processing unit (“GPU”) 1112, a Communication Processor (“CP”), and an Image Signal Processor (“ISP”). The main processor 1110 may further include a Neural Processing Unit (“NPU”) 1113. The NPU 1113 may be a processor that is specialized for operations of an Artificial Intelligence (AI) model, and the AI model may be generated through machine learning. The AI model may include a plurality of artificial neural network layers. The artificial neural network may be one of a Deep Neural Network (“DNN”), a Convolutional Neural Network (“CNN”), a Recurrent Neural Network (“RNN”), a Restricted Boltzmann Machine (“RBM”), a Deep Belief Network (“DBN”), a Bidirectional Recurrent Deep Neural Network (“BRDNN”), deep Q-networks, and a combination of at least two of the aforementioned types, but is not limited thereto. In addition to a hardware structure, the AI model may additionally or generally include a software structure. At least two of the processing units and processors stated above may be implemented as a single integrated component (e.g., a single chip) or as individual components (e.g., multiple chips).

The auxiliary processor 1120 may include a controller 1121. The controller 1121 may include an interface conversion circuit and a timing control circuit. The controller 1121 may receive image signals from the main processor 1110 and convert the data format of the image signals to comply with the interface specification with the display module 1400, thus outputting image data. The controller 1121 may output various control signals desired for the operation of the display module 1400.

The auxiliary processor 1120 may further include data processing circuits, such as a data conversion circuit 1122, a gamma correction circuit 1123, and a rendering circuit 1124. The data conversion circuit 1122 may receive image data from the controller 1121 and may adjust the image data to display images at a desired luminance according to the characteristics of the electronic apparatus 1 or the user's settings or may convert the image data to reduce power consumption or compensate for afterimages. The gamma correction circuit 1123 may convert image data, a gamma reference voltage, or the like to ensure that the images displayed on the electronic apparatus 1 exhibit desired gamma characteristics. The rendering circuit 1124 may receive image data from the controller 1121 and perform rendering on the image data by considering pixel arrangements in the display panel 10 applied to the electronic apparatus 1. At least one of the data conversion circuit 1122, the gamma correction circuit 1123, and the rendering circuit 1124 may be integrated into other components (e.g., the main processor 1110 or the controller 1121). In an embodiment, the auxiliary processor 1120 may be integrated into a data driver 1430.

The memory 1200 may store various pieces of data used by at least one component (e.g., the processor 1100 or the sensor module 1610) of the electronic apparatus 1 and input data or output data regarding commands associated with the data. The memory 1200 may include at least one or more of the volatile memory 1210 and the non-volatile memory 1220.

The input module 1300 may receive commands or data, which are to be used by a component (e.g., the processor 1100, the sensor module 1610, or the sound output module 1630) of the electronic apparatus 1, from the outside of the electronic apparatus 1 (e.g., from the user or an external electronic apparatus 2000).

The input module 1300 may include a first input module 1310, to which commands or data from the user are input, and a second input module 1320, to which commands or data from the external electronic apparatus 2000 are input.

The first input module 1310 may include a microphone, a mouse, a keyboard, or a pen (e.g., a passive pen or an active pen). The first input module 1310 may include a mechanical input medium, such as buttons disposed on the rear surface or side surfaces of the electronic apparatus 1, a dome switch, a jog wheel, or a jog switch, or a touch input medium. The touch input medium may include a touch screen layer of the display panel 10.

The second input module 1320 may connect to various types of electronic apparatuses 2000 connected to the electronic apparatus 1 in a wired or wireless manner. In an embodiment, the second input module 1320 may include, e.g., a High Definition Multimedia Interface (“HDMI”), a Universal Serial Bus (“USB”) interface, a Secure Digital (“SD”) card interface, or an audio interface. The second input module 1320 may include a connector physically connecting the electronic apparatus 1 to the external electronic apparatus 2000, e.g., an HDMI connector, a USB connector, an SD card connector, or an audio connector (e.g., a headphone connector). The electronic apparatus 1 may perform appropriate controls related to the external electronic apparatus 2000, in accordance with the connection of the external electronic apparatus 2000 to the second input module 1320.

The display module 1400 visually provides information to the user. The display module 1400 may include the display panel 10, a scan driver 1420, and a data driver 1430.

The display panel 10 displays (outputs) information processed by the electronic apparatus 1. The display panel 10 may display information regarding an execution screen of an application executed on the electronic apparatus 1, or User Interface (“UI”) information or Graphics User Interface (“GUI”) information according to the information regarding the execution screen.

The scan driver 1420 may be disposed (e.g., mounted) on the display panel 10 as a driving chip. In an alternative embodiment, the scan driver 1420 may be directly formed on the display panel 10. In an embodiment, the scan driver 1420 may include an Amorphous Silicon TFT Gate driver circuit (“ASG”), a Low Temperature Polycrystalline Silicon (“LTPS”) TFT Gate driver circuit, or an Oxide Semiconductor TFT Gate driver circuit (“OSG”), for example. The scan driver 1420 receives control signals from the controller 1121 and outputs scan signals to the display panel 10 in response to the control signals.

The display panel 10 may further include an emission control driver. The emission control driver outputs emission control signals to the display panel 10 in response to the control signals received from the controller 1121. The emission control driver may be formed either separately from the scan driver 1420 or integrally with the same.

The data driver 1430 receives control signals from the controller 1121, converts image data into data voltages in the form of analog voltages in response to the control signals, and then outputs the data voltages to the display panel 10.

The data driver 1430 may be integrated with some components of the auxiliary processor 1120. In an embodiment, the data driver 1430 may be included as a timing controller embedded driver integrated circuit (“IC”) including the controller 1121, for example.

The power module 1500 supplies power to the components of the electronic apparatus 1. The power module 1500 may include a battery that charges a power voltage. In addition, the power module 1500 may include a connection port, and the connection port may be included in the second input module 1320 that is connected to an external charger for supplying power to charge the battery. In an alternative embodiment, the power module 1500 may include a wireless power transceiver member to charge the battery in a wireless manner. The wireless power transceiver member may include a plurality of coil-shaped antenna radiators. The power module 1500 may include a Power Management Integrated Circuit (“PMIC”). The PMIC supplies power that is optimized for each component.

The electronic apparatus 1 may further include the embedded module 1600 and the external module 1700. The embedded module 1600 may include the sensor module 1610, an antenna module 1620, and the sound output module 1630. The external module 1700 may include a camera module 1710, a light module 1720, and/or a communication module 1730.

The sensor module 1610 may include touch electrodes and a touch sensor driver of the touch screen layer of the display panel 10. The sensor module 1610 may sense input from the user's body or a pen and generate an electrical signal or a data value corresponding to the input. The sensor module 1610 may include at least one of a fingerprint sensor 1611, an input sensor 1612, and a digitizer 1613.

The fingerprint sensor 1611 may generate data values corresponding to the user's fingerprints. The fingerprint sensor 1611 may include one of an optical fingerprint sensor and a capacitive fingerprint sensor.

The input sensor 1612 may generate a data value corresponding to coordinate information of input from the user's body or pen. The input sensor 1612 generates, as a data value, a variation in capacitance caused by the input. The input sensor 1612 may sense an input from a passive pen or exchange data with an active pen.

The input sensor 1612 may also measure biometric signals, such as blood pressure, body moisture, or body fat. In an embodiment, when the user touches a sensor layer or a sensing panel with a body part and remains stationary for a predetermined period of time, the input sensor 1612 may sense a biometric signal based on a change in electric field caused by the body part, thus outputting information that the user desires to the display module 1400, for example.

The digitizer 1613 may generate a data value corresponding to coordinate information of a pen input. The digitizer 1613 generates, as a data value, an electromagnetic variation caused by an input. The digitizer 1613 may sense an input from a passive pen or exchange data with an active pen.

In an embodiment, at least one of the fingerprint sensor 1611, the input sensor 1612, and the digitizer 1613 may be embedded in the display panel 10. In an embodiment, at least one of the fingerprint sensor 1611, the input sensor 1612, and the digitizer 1613 may be formed through a process that follows the process of forming the pixel circuits and light-emitting diodes of the display panel 10, for example. To this end, the display panel 10 may function as one of the input modules 1300 that provide an input interface between the electronic apparatus 1 and the user, and also function as the display module 1400 that provides an output interface between the electronic apparatus 1 and the user.

In an embodiment, at least two of the fingerprint sensor 1611, the input sensor 1612, and the digitizer 1613 may be integrated into a single sensing panel through the same process. The sensing panel may be disposed between the display panel 10 and the window disposed on an upper side of the display panel 10, but the disclosure is not limited thereto.

The antenna module 1620 may include one or more antennas for transmitting signals or power to the outside or receiving the same from the outside. In an embodiment, the communication module 1730 may transmit signals to an external electronic apparatus or receive signals therefrom through an antenna that is suitable for the communication method. The antenna pattern of the antenna module 1620 may be integrated into the input sensor 1612 or one component (e.g., the display panel 10) of the display module 1400.

The sound output module 1630 may be a device for outputting sound signals to the exterior of the electronic apparatus 1 and may output sound data that is received from the communication module 1730 or stored in the memory 1200 in a call signal reception mode, a call or recording mode, a voice recognition mode, a broadcast reception mode, or the like. The sound output module 1630 may output sound signals related to functions performed by the electronic apparatus 1 (e.g., call signal receiving sound, message notification sound, etc.) The sound output module 1630 may include a receiver and a speaker. At least one of the receiver and the speaker may be a sound generating device that is attached to a lower portion of the display panel 10 and outputs sound by vibrating the display panel 10. The sound generating device may be a piezoelectric element or a piezoelectric actuator that contracts and expands according to electrical signals or may be an exciter that generates magnetic force using voice coils and vibrates the display panel 10.

The camera module 1710 may capture still and moving images. In an embodiment, the camera module 1710 may include one or more lenses, an image sensors, or an image signal processor. The camera module 1710 may further include an infrared camera that may detect the user's presence, location, gaze, or the like.

The light module 1720 may output a signal to notify the occurrence of events by light from a light source or provide light for image acquisition. Here, embodiments of the occurrence of events may include message reception, call signal reception, missed calls, notifications, schedule notifications, e-mail reception, and battery capacity information notifications. The light module 1720 may include light-emitting diodes or a xenon lamp. The light module 1720 may emit light of a single color or different colors to the front surface or rear surface of the electronic apparatus 1. The light module 1720 may operate in conjunction with or independently from the camera module 1710.

The communication module 1730 may support communication by establishing wired or wireless communication channels between the electronic apparatus 1 and the external electronic apparatus 2000 and by established communication channels. The communication module 1730 may include at least one or all of a wireless communication module, such as a cellular communication module, a short-range wireless communication module, or a Global Navigation Satellite System (“GNSS”) communication module, and a wired communication module, such as a Local Area Network (“LAN”) communication module or a power line communication module. The communication module 1730 may receive/transmit wireless signals from/to the Internet using at least one of Wireless LAN (“WLAN”), Wireless-Fidelity (“Wi-Fi^{®}”, Wi‑Fi^{®} being a registered trademark of the non-profit Wi-Fi Alliance), Wi-Fi Direct^{TM} (Wi-Fi Direct^{TM} being a registered trademark of the non-profit Wi-Fi Alliance), and Digital Living Network Alliance (“DLNA”) technologies. In addition, the communication module 1730 may support short-range communication by at least one of Bluetooth^{®} (Bluetooth^{®} being a registered trademark of Bluetooth Sig, Inc., Kirkland, WA), Radio Frequency Identification (“RFID”), Infrared Data Association (“IrDA”), Ultra Wideband (“UWB”), ZigBee^{®} (ZigBee^{®} being a registered trademark of Connectivity Standards Alliance, CA), Near Field Communication (“NFC”), Wi-Fi^{®}, Wi-Fi Direct^{TM}, and Wireless USB technologies. Various types of communication modules 1730 described above may be implemented as a single chip or separate chips.

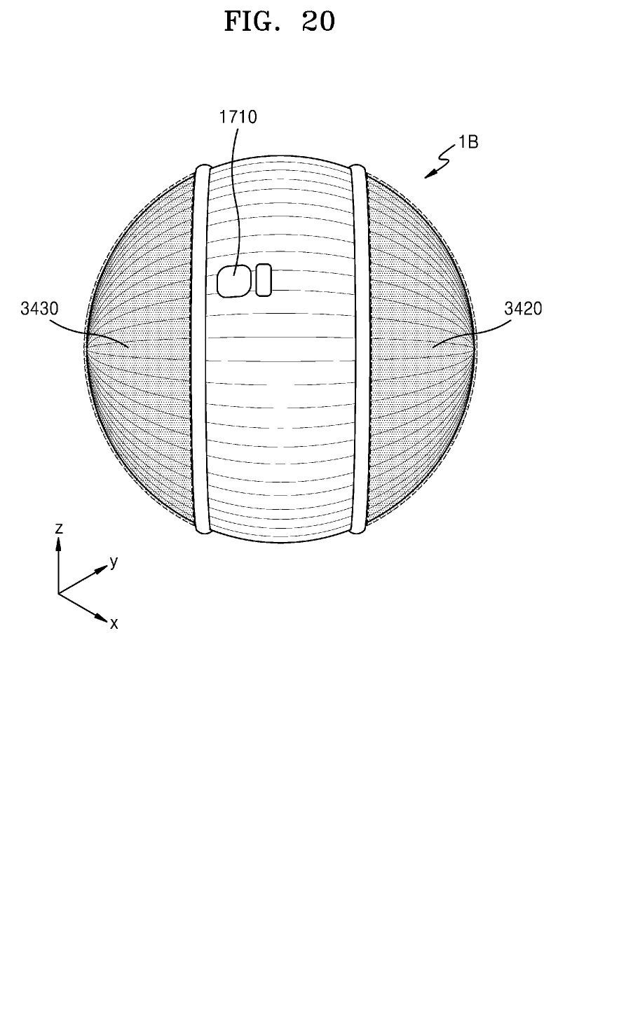

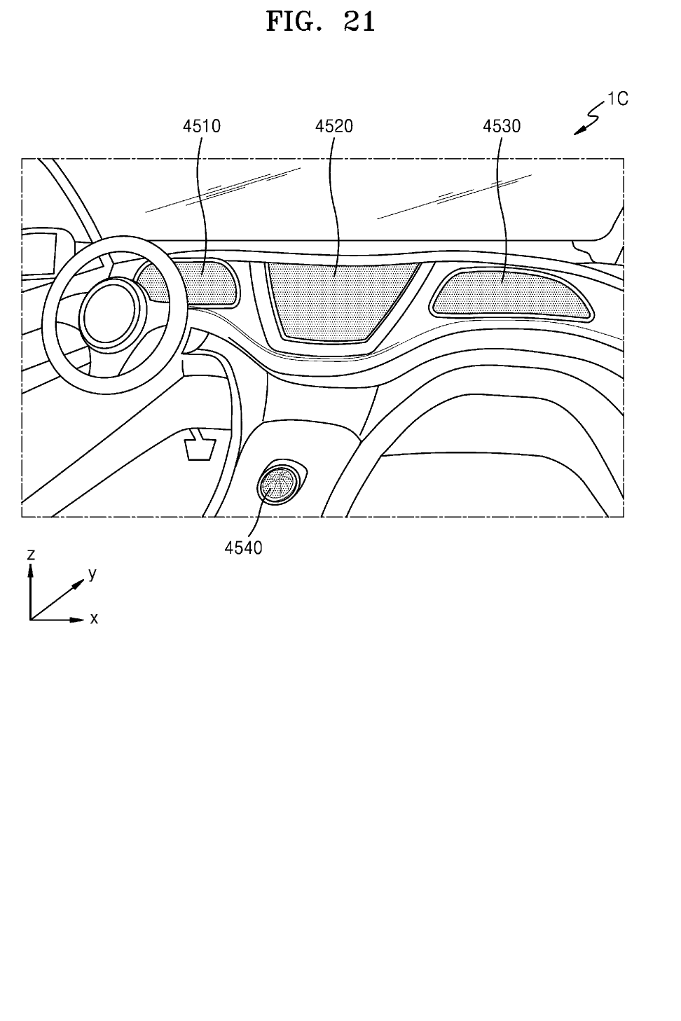

In the embodiments described with reference to FIGS. 17 and 18, it is described that the display panel 10 is included in the electronic apparatus 1 that provides a three-dimensionally changeable image plane by undergoing free three-dimensional deformation, but the disclosure is not limited thereto. As shown in FIGS. 20 and 21, an electronic apparatus may include an image provision area with a fixed shape, and during the manufacturing process for the electronic apparatus, the display panel may be disposed in the image provision area of the above electronic apparatus and fixed to the electronic apparatus in a three-dimensionally deformed state.

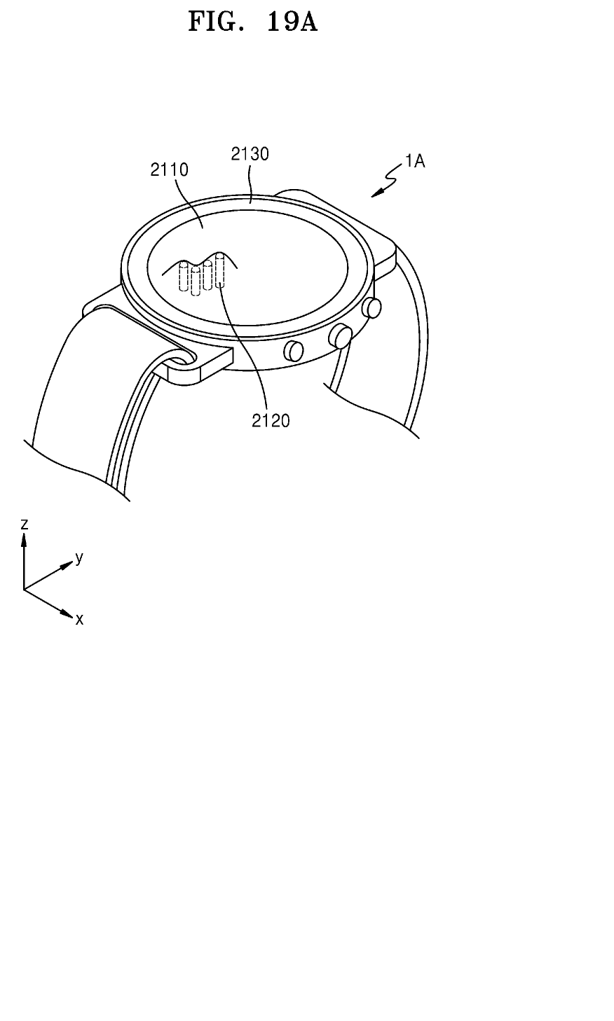

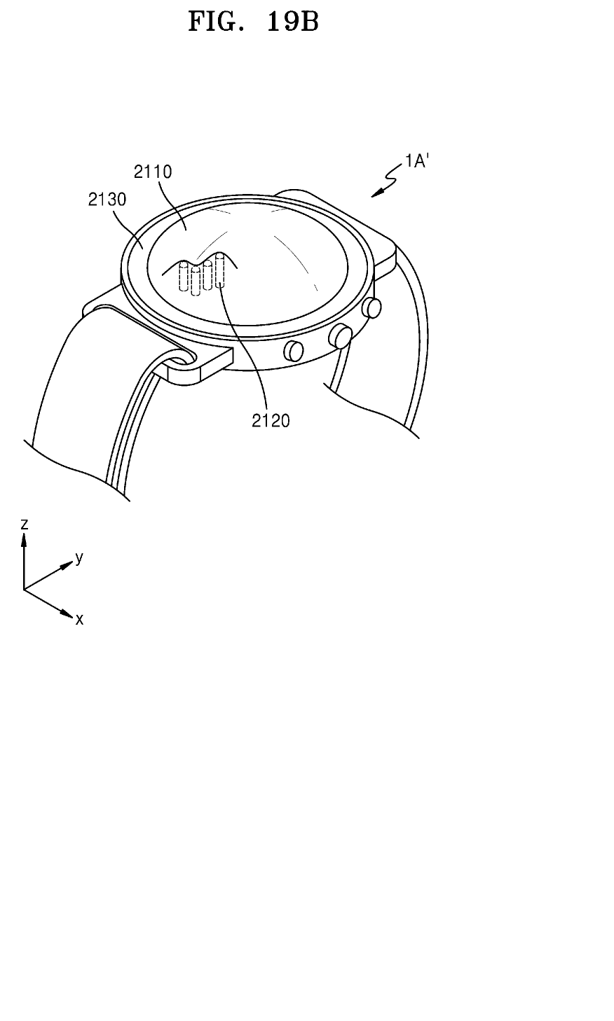

FIGS. 19A to 21 are respectively perspective views of electronic apparatuses. Electronic apparatuses 1A, 1A', 1B, and 1C shown in FIGS. 19A to 21 may each include components of the electronic apparatus 1 described with reference to FIG. 18.

FIGS. 19A and 19B illustrate the electronic apparatuses 1A and 1A' as smart watches. In an embodiment, a display section 2110 of the smart watch may include the display panel described with reference to FIGS. 1 to 16. In an embodiment, because the display panel corresponding to the display section 2110 is three-dimensionally stretchable, various pieces of haptic information may be provided to the user. In an embodiment, haptic information or visual information may be provided to the user due to the movements of strokes 2120 arranged under the display section 2110, for example. In an embodiment, the display panel may be three-dimensionally stretched as the strokes 2120 move in the third direction (e.g., the z direction or the -z direction), and thus, images displayed on the display section 2110 may be implemented to have a three-dimensional height. In an alternative embodiment, as the strokes 2120 move in the third direction (e.g., the z direction or the -z direction), haptic information (e.g., Braille information for the visually impaired) may be provided to the user through the display section 2110 (or the display panel). The display panel corresponding to the display section 2110 and the strokes 2120 may be accommodated in or assembled to a frame (or housing) 2130.

FIG. 19A illustrates that the display section 2110 has a flat shape while not being three-dimensionally stretched (e.g., the state in which the electronic apparatus 1A is off), but the disclosure is not limited thereto. As shown in FIG. 19B, while not being three-dimensionally stretched (while the electronic apparatus 1A’ is off), the display section 2110 may have a dome shape.

FIGS. 19A and 19B illustrate three-dimensionally stretchable smart watches, but the disclosure is not limited thereto. In another embodiment, because the display panel of the smart watch is three-dimensionally stretchable, the display panel may be fixed and assembled to a body frame while being three-dimensionally stretched along the body frame with a predetermined shape (e.g., a hemispherical shape) during the manufacturing process for the smart watch, thereby forming the display section 2110. The display section 2110 of the smart watch may not be three-dimensionally deformed.

FIG. 20 illustrate an embodiment of a robot as another electronic apparatus 1B. The robot may move or identify objects by the camera module 1710 and display predetermined images for the user through displays 3420 and 3430. In some embodiments, because the display panels in an embodiment are stretchable in various directions as described above, the display panels may be assembled to the frame of the electronic apparatus 1B while being stretched three-dimensionally along a body frame with a hemispherical shape, thereby forming the display sections 3420 and 3430.

FIG. 21 illustrates a vehicle display device as another electronic apparatus 1C. The vehicle display device may include a cluster 4510, a Center Information Display (“CID”) 4520, and/or a passenger display 4530. Because the display panel in an embodiment may be stretched in various directions, the display panel may be used for the cluster 4510, the CID 4520, and/or the passenger display 4530, regardless of the shape of the internal frame of the vehicle.

FIG. 21 illustrates that the cluster 4510, the CID 4520, and/or the passenger display 4530 are separate from each other, but the disclosure is not limited thereto. In another embodiment, two or more components selected from the cluster 4510, the CID 4520, and the passenger display 4530 may be integrally connected.

In some embodiments, the vehicle display device may include a button 4540 that may display predetermined images. The button 4540 having a hemispherical shape may sense a touch input from a user (e.g., a driver) in the z direction or -z direction. In some embodiments, the button 4540 shown in FIG. 21 may include the strokes described with reference to FIGS. 19A and 19B.

FIGS. 19A to 21 illustrate that the electronic apparatuses 1A, 1A', 1B, and 1C are wearable electronic devices worn on a body part, a robot, or a vehicle electronic device, but the disclosure is not limited thereto. The electronic apparatuses of the disclosure may include electronic apparatuses for various purposes, such as commercial electronic apparatuses, office electronic apparatuses, educational electronic apparatuses, wearable electronic apparatuses, and medical electronic apparatuses. In other words, the display panel in an embodiment may be included in various electronic apparatuses as long as it includes an area where images may be provided.

According to the embodiments, a display panel that may produce high-quality images and may be stretched may be provided. The above effect is merely one of embodiments, and the scope of the disclosure is not limited thereto.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
a substrate;
a pixel circuit layer on the substrate, the pixel circuit layer comprising:
a pixel circuit comprising:
a driving transistor comprising:
a semiconductor layer; and
a gate electrode; and
a storage capacitor; and
a plurality of insulating layers comprising:
a first insulating layer disposed between the semiconductor layer and the gate electrode, the first insulating layer comprising:
a first inorganic material portion overlapping the gate electrode; and
a first organic material portion around the first inorganic material portion; and
a light-emitting diode on the pixel circuit layer and electrically connected to the pixel circuit.

2. The display panel of claim 1, wherein an upper surface of the first inorganic material portion and an upper surface of the first organic material portion are arranged in a same plane.

3. The display panel of claim 1, wherein, in a plan view, the first organic material portion surrounds an entirety of the first inorganic material portion.

4. The display panel of claim 1, wherein the first organic material portion comprises:
a 1-1^{st} organic material portion which overlaps the semiconductor layer; and
a 1-2^{nd} organic material portion which does not overlap the semiconductor layer, and
a thickness of the first inorganic material portion is less than a thickness of the 1-2^{nd} organic material portion.

5. The display panel of claim 4, wherein a thickness of the 1-1^{st} organic material portion is substantially a same as the thickness of the first inorganic material portion.

6. The display panel of claim 1, wherein the plurality of insulating layers further comprises a second insulating layer disposed between a first electrode and a second electrode of the storage capacitor, and
the second insulating layer comprises a second inorganic material portion overlapping the first electrode and the second electrode and a second organic material portion around the second inorganic material portion.

7. The display panel of claim 6, wherein an upper surface of the second inorganic material portion and an upper surface of the second organic material portion are arranged in a same plane.

8. The display panel of claim 6, wherein the second inorganic material portion overlaps the first inorganic material portion.

9. The display panel of claim 1, wherein the pixel circuit layer comprises:
a switching transistor electrically connected to the driving transistor; and
a connector connecting to a semiconductor layer of the switching transistor, and
the connector directly contacts the semiconductor layer of the switching transistor through a contact hole which penetrates insulating layers arranged between the semiconductor layer of the switching transistor and the connector among the plurality of insulating layers, the contact hole passing through each of organic material portions of the insulating layers arranged between the semiconductor layer and the connector.

10. An electronic apparatus comprising a display section, the electronic apparatus comprising:
a frame;
a display panel assembled to the frame and corresponding to the display section, the display panel comprising:
a substrate;
a pixel circuit layer on the substrate, the pixel circuit layer comprising:
a pixel circuit comprising:
a driving transistor comprising:
a semiconductor layer; and
a gate electrode; and
a storage capacitor; and
insulating layers comprising:
a first insulating layer between the substrate and the semiconductor layer;
a second insulating layer between the semiconductor layer and the gate electrode; and
a third insulating layer on the second insulating layer; and
a light-emitting diode on the pixel circuit layer and electrically connected to the pixel circuit; and
a stroke assembled to the frame and disposed under the display panel,
wherein at least one of the first insulating layer to the third insulating layer comprises a plurality of inorganic material portions spaced apart from each other and an organic material portion which surrounds each of the plurality of inorganic material portions in a plan view.

11. The electronic apparatus of claim 10, comprising a wearable electronic apparatus.

12. The electronic apparatus of claim 10, wherein the display panel is three-dimensionally stretchable by the stroke.

13. The electronic apparatus of claim 12, wherein the display section has a dome shape when the display panel is not three-dimensionally stretched.

14. The electronic apparatus of claim 10, wherein an upper surface of each of the plurality of inorganic material portions and an upper surface of the organic material portion are arranged in a same plane.

15. The electronic apparatus l of claim 10, wherein the first insulating layer comprises a first inorganic material portion which overlaps the semiconductor layer and a first organic material portion around the first inorganic material portion.

16. The electronic apparatus of claim 10, wherein the second insulating layer comprises a second inorganic material portion which overlaps the gate electrode and a second organic material portion around the second inorganic material portion,
wherein the second organic material portion comprises:
a 2-1^{st} organic material portion which overlaps the semiconductor layer; and
a 2-2^{nd} organic material portion which does not overlap the semiconductor layer,
a thickness of the 2-2^{nd} organic material portion is greater than a thickness of the 2-1^{st} organic material portion.

17. The electronic apparatus of claim 16, wherein a thickness of the second inorganic material portion is less than the thickness of the 2-2^{nd} organic material portion, and the thickness of the second inorganic material portion is substantially a same as the thickness of the 2-1^{st} organic material portion.

18. The electronic apparatus of claim 16, wherein the storage capacitor comprises a first electrode and a second electrode, the first electrode of the storage capacitor is integrally coupled to the gate electrode, and
the third insulating layer comprises a third inorganic material portion overlapping the first electrode and the second electrode of the storage capacitor and a third organic material portion around the third inorganic material portion.

19. The electronic apparatus of claim 18, wherein an upper surface of the second inorganic material portion and an upper surface of the second organic material portion are arranged in a same plane, and the third inorganic material portion overlaps the second inorganic material portion.

20. The electronic apparatus of claim 10, wherein the pixel circuit layer comprises:
a switching transistor electrically connected to the driving transistor; and
a connector connecting to a semiconductor layer of the switching transistor, and
the connector directly contacts the semiconductor layer of the switching transistor through a contact hole which penetrates insulating layers arranged between the semiconductor layer of the switching transistor and the connector among the plurality of insulating layers, the contact hole passing through each of organic material portions of the insulating layers arranged between the semiconductor layer and the connector.
